(19) United States
(12) Patent Application Publication
(10) Pub. No.: US 2023/0178476 A1
(43) Pub. Date: Jun. 8, 2023

(54) INTEGRATED CIRCUIT DEVICE

(71) Applicant: SAMSUNG ELECTRONICS CO., LTD., Suwon-si (KR)

(72) Inventors: Hyunwoo KANG, Suwon-si (KR); Yoontae HWANG, Seoul (KR); Geunwoo KIM, Seoul (KR); Sunghwan KIM, Hwaseong-si (KR); Junki PARK, Hwaseong-si (KR)

(21) Appl. No.: 17/864,716

(22) Filed: Jul. 14, 2022

(30) Foreign Application Priority Data
Dec. 8, 2021 (KR) 10-2021-0175211

(51) Int. Cl. H01L 23/522; H01L 21/768

(52) U.S. Cl. CPC H01L 23/5226; H01L 21/76805; H01L 21/76831; H01L 23/53266

(57) ABSTRACT

An integrated circuit device includes a conductive region disposed on a substrate, an insulating structure including a contact hole disposed in the conductive region and extending from the conductive region in a vertical direction, a local capping pattern having an outer sidewall in contact with an upper portion of an inner wall of the contact hole and an inner sidewall facing an inside of the contact hole and having a width gradually increasing in a horizontal direction away from the substrate, and a conductive plug passing through the insulating structure through the contact hole in the vertical direction, having a lower sidewall in contact with the insulating structure and an upper sidewall in contact with the local capping pattern, and including a first metal.

### CROSS-REFERENCE TO RELATED APPLICATION

This application is based on and claims priority under 35 U.S.C. § 119 to Korean Patent Application No. 10-2021-0175211, filed on Dec. 8, 2021, in the Korean Intellectual Property Office, the disclosure of which is incorporated by reference herein in its entirety.

### BACKGROUND

### 1. Field

Embodiments relate to an integrated circuit (IC) device.

### 2. Description of the Related Art

Due to the development of electronics technology, IC devices have been rapidly downscaled, and accordingly, line widths and pitches of metal wiring layers included in IC devices have also been reduced.

### SUMMARY

An embodiment is directed to an integrated circuit device including a conductive region disposed on a substrate, an insulating structure including a contact hole disposed on the conductive region and extending from the conductive region in a vertical direction, a local capping pattern having an outer sidewall in contact with an upper portion of an inner wall of the contact hole and an inner sidewall facing an inside of the contact hole and having a width gradually increasing in a horizontal direction, away from the substrate, and a conductive plug passing through the insulating structure through the contact hole in the vertical direction, having a lower sidewall in contact with the insulating structure and an upper sidewall in contact with the local capping pattern, and including a first metal.

An embodiment is directed to an integrated circuit device including a source/drain region disposed on a substrate and a recess surface on an upper surface thereof, a metal silicide layer disposed on the recess surface of the source/drain region and including a first metal, an insulating structure including a contact hole disposed on the metal silicide layer and extending from the metal silicide layer in a vertical direction, a local capping pattern having an outer sidewall in contact with an upper portion of an inner wall of the contact hole away from the substrate and an inner sidewall facing an inside of the contact hole, and having a width gradually increasing in a horizontal direction, away from the substrate, and a conductive plug passing through the insulating structure through the contact hole in the vertical direction, having a lower sidewall in contact with the insulating structure and an upper sidewall in contact with the local capping pattern, and including a second metal that is different from the first metal.

An embodiment is directed to an integrated circuit device including a fin-type active region protruding from a substrate, a source/drain region disposed in the fin-type active region, a metal silicide layer in contact with an upper surface of the source/drain region, a gate line extending from the fin-type active region in a direction intersecting the fin-type active region, an insulating structure disposed in the source/drain region, the metal silicide layer, and the gate line, a source/drain contact structure passing through a first portion of the insulating structure and connected to the source/drain region through the metal silicide layer, and a gate contact structure passing through a second portion of the insulating structure in a vertical direction and configured to be connected to the gate line, wherein at least one of the source/drain contact structure and the gate contact structure includes a local capping pattern having an outer sidewall in contact with an upper portion of an inner wall of a contact hole formed in the insulating structure and an inner sidewall facing an inside of the contact hole and having a width gradually increasing in a horizontal direction, away from the substrate and a conductive plug passing through the insulating structure through the contact hole in a vertical direction, having a lower sidewall in contact with the insulating structure and an upper sidewall in contact the local capping pattern, and including a first metal.

### BRIEF DESCRIPTION OF THE DRAWINGS

Features will become apparent to those of skill in the art by describing in detail example embodiments with reference to the attached drawings in which:

FIG. 1 is a plan layout diagram illustrating an integrated circuit (IC) device according to example embodiments;

FIG. 2A is a cross-sectional view showing a partial configuration of a cross-section taken along line X1-X1′ and a cross-section taken along line X2-X2′ of FIG. 1, FIG. 2B is a cross-sectional view showing a partial configuration of a cross-section taken along line Y1-Y1′ of FIG. 1, FIG. 2C is an enlarged cross-sectional view of a portion EX1 in FIG. 2A, and FIG. 2D is an enlarged cross-sectional view of a portion EX2 in FIG. 2B;

FIG. 2E is a cross-sectional view illustrating an IC device according to other example embodiments;

FIG. 3 is a cross-sectional view illustrating an IC device according to still other example embodiments;

FIG. 4 is a cross-sectional view illustrating main components of an IC device according to still other example embodiments;

FIG. 5 is a cross-sectional view illustrating an IC device according to still other example embodiments;

FIG. 6 is a plan layout diagram of some components of an IC device according to still other example embodiments;

FIG. 7A is a cross-sectional view taken along line X4-X4′ of FIG. 6, and FIG. 7B is a cross-sectional view taken along line Y4-Y4′ of FIG. 6;

FIGS. 8A to 8I are cross-sectional views illustrating a process sequence of a method of manufacturing an IC device, according to example embodiments; and

FIGS. 9A to 15 are cross-sectional views illustrating a process sequence of a method of manufacturing an IC device, according to other example embodiments, in which FIGS. 9A, 10A, 11A, 12A, 13A, 14A, and 15 are cross-sectional views according to a process sequence of portions corresponding to the cross-section X4-X4′ of FIG. 6, and FIGS. 9B, 10B, 11B, 12B, 13B, and 14B are cross-sectional views illustrating a process sequence of portions corresponding to the cross-section Y4-Y4′ of FIG. 6.

### DETAILED DESCRIPTION

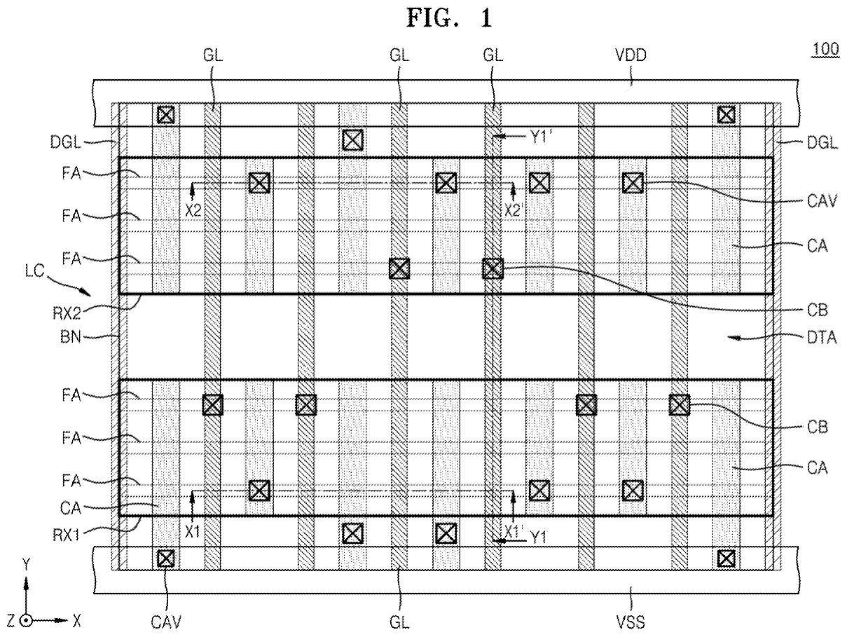

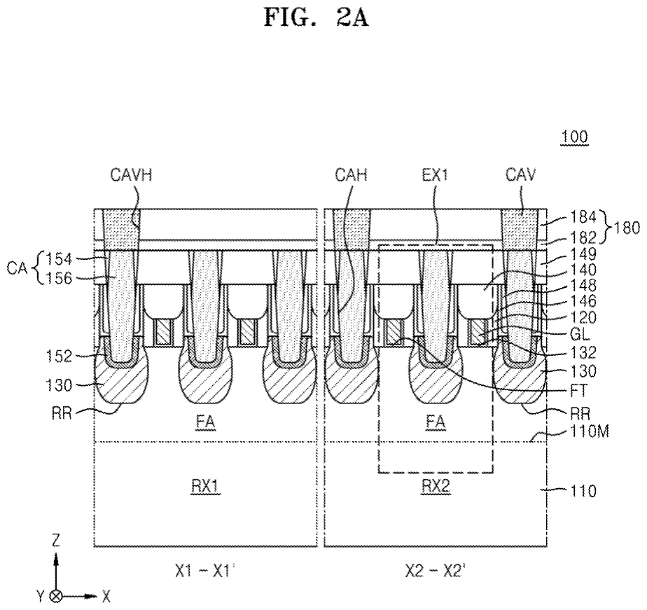

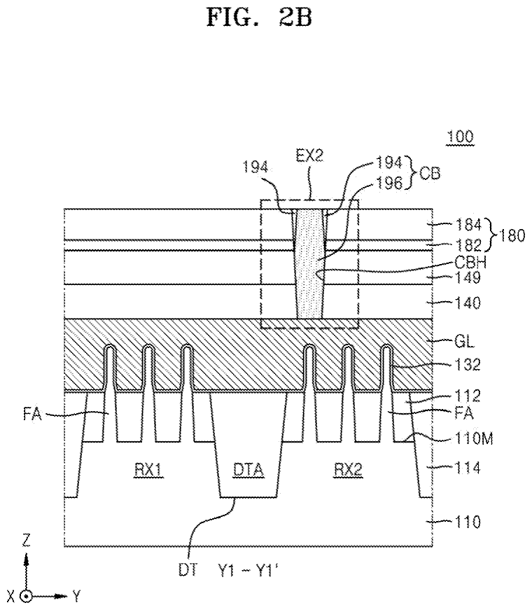

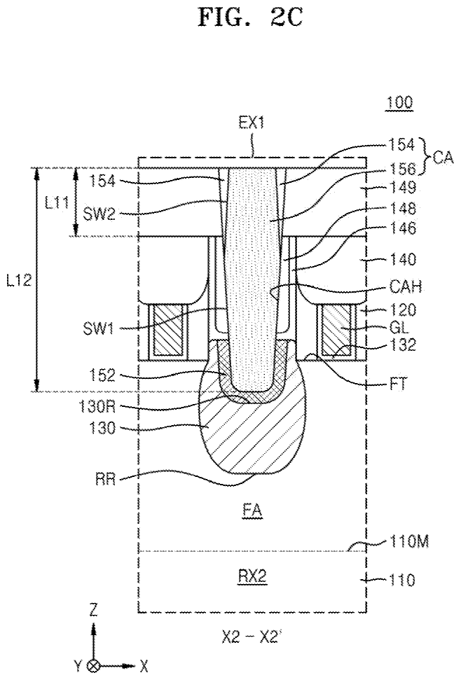

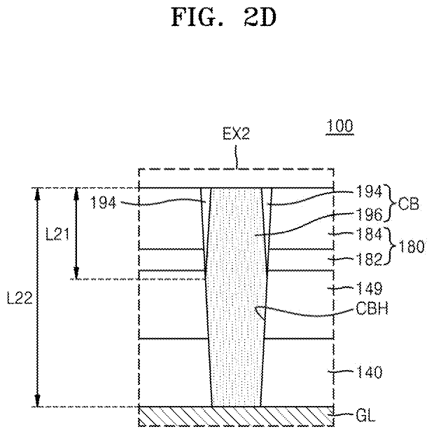

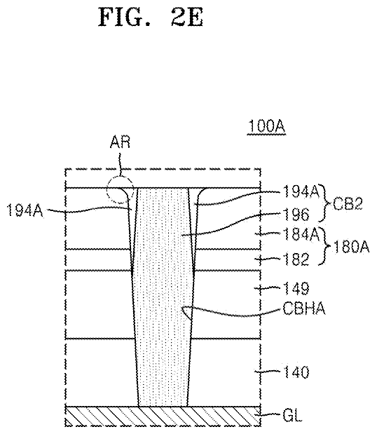

FIG. 1 is a plan layout diagram illustrating an integrated circuit (IC) device 100 according to example embodiments. FIG. 2A is a cross-sectional view showing a partial configuration of a cross-section taken along line X1-X1′ and a cross-section taken along line X2-X2′ of FIG. 1, FIG. 2B is a cross-sectional view showing a partial configuration of a cross-section taken along line Y1-Y1′ of FIG. 1, FIG. 2C is an enlarged cross-sectional view of a portion EX1 in FIG. 2A, and FIG. 2D is an enlarged cross-sectional view of a portion EX2 in FIG. 2B.

Referring to FIGS. 1 and 2A to 2D, the IC device 100 may constitute a logic cell including a fin field effect transistor (FinFET) device. The IC device 100 may include a logic cell LC formed in a region defined by a cell boundary BN on a substrate 110.

The substrate 110 may have a main surface 110M extending in a horizontal direction (X-Y plane direction). The substrate 110 may include an elemental semiconductor, such as Si or Ge, or a compound semiconductor, such as SiGe, SiC, GaAs, InAs, or InP. The substrate 110 may include a conductive region, e.g., a well that is doped with an impurity or a structure that is doped with an impurity.

The logic cell LC may include a first device region RX1 and a second device region RX2. Fin-type active regions FA protruding from the substrate 110 may be disposed in the first device region RX1 and the second device region RX2, respectively. The fin-type active regions FA may extend parallel to each other in a width direction of the logic cell LC, that is, in a first horizontal direction (an X direction).

Referring to FIG. 2B, a device separation layer 112 may be disposed in the first device region RX1 and the second device region RX2 on the substrate 110. The device separation layer 112 may be disposed between each of the fin-type active regions FA, and may cover a lower sidewall of the fin-type active region FA. In the first device region RX1 and the second device region RX2, the fin-type active regions FA may protrude in a fin shape over the device separation layer 112. An inter-device separation region DTA may be disposed between the first device region RX1 and the second device region RX2. A deep trench DT defining the first device region RX1 and the second device region RX2 may be formed in the device separation region DTA, and the deep trench DT may be filled with an inter-device separation insulating layer 114. The device separation layer 112 and the inter-device separation insulating layer 114 may each include an oxide layer.

On the substrate 110, a plurality of gate insulating layers 132 and a plurality of gate lines GL may extend in a height direction of the logic cell LC in FIG. 1, i.e., in a second horizontal direction (a Y direction), intersecting with the fin-type active regions FA. The gate insulating layers 132 and the gate lines GL may cover a top surface and both sidewalls of each of the fin-type active regions FA, an upper surface of the device separation layer 112, and a top surface of the inter-device separation insulating layer 114.

A plurality of MOS transistors may be formed along the gate lines GL in the first device region RX1 and the second device region RX2. Each of the MOS transistors may be a MOS transistor having a three-dimensional (3D) structure in which channels are formed on the top surface and both sidewalls of the fin-type active regions FA. In example embodiments, the first device region RX1 may be an NMOS transistor region, and a plurality of NMOS transistors may be formed in portions in which the fin-type active region FA and the gate line GL intersect each other in the first device region RX1. The second device region RX2 may be a PMOS transistor region, and a plurality of PMOS transistors may be formed in portions in which the fin-type active region FA intersects with the gate line GL in the second device region RX2.

Referring to FIG. 1, a dummy gate line DGL may extend along a portion of the cell boundary BN extending in the second horizontal direction (the Y direction). The dummy gate line DGL may be formed of the same material as that of the gate lines GL. The dummy gate line DGL may maintain an electrically floating state during the operation of the IC device 100, thereby functioning as an electrical separation region between the logic cell LC and other logic cells surrounding the logic cell LC. The gate lines GL and the dummy gate lines DGL may each have the same width in the first horizontal direction (the X direction) and may be arranged at a constant pitch in the first horizontal direction (the X direction).

The gate insulating layers 132 may include a silicon oxide layer, a high-k layer, or a combination thereof. The high-k layer may be formed of a material having a higher dielectric constant than that of the silicon oxide layer. The high-k layer may be formed of a metal oxide or a metal oxynitride. An interface layer (not shown) may be interposed between the fin-type active region FA and the gate insulating layer 132. The interface layer may include an oxide layer, a nitride layer, or an oxynitride layer.

Each of the gate lines GL and the dummy gate lines DGL may have a structure in which a metal nitride layer, a metal layer, a conductive capping layer, and a gap-fill metal layer are sequentially stacked. The metal nitride layer and the metal layer may include at least selected from titanium (Ti), tantalum (Ta), tungsten (W), ruthenium (Ru), niobium (Nb), molybdenum (Mo), and hafnium (Hf). The gap-fill metal layer may include a W layer or an Al layer. Each of the gate lines GL and the dummy gate lines DGL may include a work function metal-containing layer. The work function metal-containing layer may include at least one metal selected from titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). In example embodiments, the gate lines GL and the dummy gate lines DGL may each include a stacked structure of TiAlC/TiN/W, a stacked structure of TiN/TaN/TiAlC/TiN/W, or a stacked structure of TiN/TaN/TiN/TiAlC/TiN/W, for example.

A plurality of insulating spacers 120 may cover both sidewalls of the gate lines GL and the dummy gate lines DGL. The gate lines GL, the dummy gate lines DGL, the gate insulating layers 132, and the insulating spacers 120 may be covered with a plurality of insulating capping lines 140. The insulating capping lines 140 and the insulating spacers 120 may each extend in a line shape in the second horizontal direction (the Y direction).

Each of the insulating spacers 120 may be formed of silicon nitride (SiN), SiCN, SiBN, SiON, SiOCN, SiBCN, or a combination thereof, for example. The insulating capping lines 140 may be formed of SiN. As used herein, the terms “SiN”, “SiCN”, “SiBN”, “SiON”, “SiOCN”, and “SiBCN” refer to a material including elements included in each term, and is not a chemical formula that indicates a stoichiometric relationship.

A plurality of recess regions RR may be formed in top surfaces of the fin-type active regions FA. The gate lines GL may include a pair of gate lines GL disposed adjacent to one recess region RR and apart from each other with the one recess region RR therebetween. A plurality of source/drain regions 130 may be disposed in the recess regions RR. The source/drain regions 130 may include a source/drain region 130 interposed between a pair of gate lines GL. The gate line GL and the source/drain region 130 may be apart from each other with the gate insulating layer 132 and the insulating spacer 120 therebetween.

The source/drain regions 130 may include epitaxial semiconductor layers that are epitaxially grown from the recess regions RR. For example, the source/drain regions 130 may include an epitaxially grown Si layer, an epitaxially grown SiC layer, or a plurality of epitaxially grown SiGe layers. When the first device region RX1 is an NMOS transistor region and the second device region RX2 is a PMOS transistor region, the source/drain regions 130 in the first device region RX1 may be formed of an n-type dopant or include a SiC layer doped with an n-type dopant, and the source/drain regions 130 in the second device region RX2 may include a SiGe layer doped with a p-type dopant. The n-type dopant may be selected from phosphorus (P), arsenic (As), and antimony (Sb). The p-type dopant may be selected from boron (B) and gallium (Ga).

In example embodiments, the source/drain regions 130 in the first device region RX1 and the source/drain regions 130 in the second device region RX2 may have different shapes and sizes. The shape of each of the source/drain regions 130 may be varied from those illustrated in FIGS. 2A and 2C, and source/drain regions 130 having various shapes and sizes may be formed in the first device region RX1 and the second device region RX2.

Referring to FIG. 2C, each of the source/drain regions 130 may have a recess surface 130R on a top surface thereof. A plurality of metal silicide layers 152 may be disposed on the recess surface 130R of each of the source/drain regions 130. The metal silicide layers 152 may cover top surfaces of the source/drain regions 130, respectively. The source/drain regions 130 and the metal silicide layers 152 may constitute conductive regions, respectively.

Each of the metal silicide layers 152 may include a first metal. In example embodiments, the first metal may be Ti, W, Ru, Nb, Mo, Hf, Ni, Co, Pt, Yb, Tb, Dy, Er, or Pd. For example, the metal silicide layer 152 may be formed of titanium silicide.

An insulating liner 146 and an inter-gate insulating layer 148 may be sequentially disposed on the source/drain regions 130 and the metal silicide layers 152. The insulating liner 146 and the inter-gate insulating layer 148 may constitute a lower insulating structure. In example embodiments, the insulating liner 146 may be formed of, e.g., silicon nitride (SiN), SiCN, SiBN, SiON, SiOCN, SiBCN, or a combination thereof. The inter-gate insulating layer 148 may include a silicon oxide layer, for example.

The IC device 100 may include a plurality of the insulating capping lines 140, the insulating liner 146, and an insulating layer 149 covering a top surface of each of the inter-gate insulating layers 148. In example embodiments, the insulating layer 149 may include a silicon oxide layer, for example.

The insulating capping lines 140, the insulating liner 146, and the inter-gate insulating layer 148 may constitute an insulating structure. A plurality of source/drain contact holes CAH may be formed in the metal silicide layer 152 and extending from the metal silicide layer 152 in a vertical direction (a Z direction). The source/drain contact holes CAH may pass through the insulating layer 149, the inter-gate insulating layer 148, and the insulating liner 146 of the insulating structure in the vertical direction (the Z direction).

The source/drain contact holes CAH may be filled with a plurality of source/drain contact structures CA. Each of the source/drain contact structures CA may be configured to pass through the insulating layer 149, the inter-gate insulating layer 148, and the insulating liner 146 in the vertical direction (the Z direction) to be connected to the source/drain region 130 through the metal silicide layer 152. Each of the source/drain contact structures CA may be apart from the gate line GL in the first horizontal direction (the X direction) with at least a portion of the insulating spacer 120 and the inter-gate insulating layer 148 therebetween. Each of the source/drain regions 130 may be connected to an upper conductive line through the metal silicide layer 152 and the source/drain contact structure CA.

Each of the source/drain contact structures CA may include a local capping pattern 154 and a conductive plug 156 in the source/drain contact hole CAH.

The local capping pattern 154 may be disposed concentrically with the conductive plug 156, and may have a ring shape surrounding an upper end of the conductive plug 156 when viewed in a plan view (e.g., an X-Y plane). An outer sidewall of the local capping pattern 154 may contact an upper portion of the inner wall of the source/drain contact hole CAH, which is relatively far from the substrate 110. An inner sidewall of the local capping pattern 154 may face the inside of the source/drain contact hole CAH, and may contact the upper end of the conductive plug 156. The local capping pattern 154 may have a width gradually increasing in a horizontal direction (e.g., the X-direction and the Y-direction) away from the substrate 110.

Referring to FIGS. 2A and 2C, the conductive plug 156 may pass through the insulating layer 149, the inter-gate insulating layer 148, and the insulating liner 146 through the source/drain contact hole CAH in the vertical direction (the Z direction). A lower sidewall SW1 of the conductive plug 156 that is relatively close to the substrate 110 may contact at least a portion of the insulating layer 149, the inter-gate insulating layer 148, and the insulating liner 146. An upper sidewall SW2 of the conductive plug 156 that is relatively far from the substrate 110 may contact the local capping pattern 154. A top surface of the local capping pattern 154, a top surface of the conductive plug 156, and a top surface of the insulating layer 149 may extend in a horizontal direction on the same plane.

The upper sidewall SW2 of the conductive plug 156 may include an inclined surface that is inclined horizontally away from the insulating structure including the insulating layer 149, the inter-gate insulating layer 148, and the insulating liner 146 in a direction away from the substrate 110. Accordingly, a width of an upper portion of the conductive plug 156, defined by the upper sidewall SW2 of the conductive plug 156, may gradually decrease in the horizontal direction (e.g., the X and Y directions) in a direction away from the substrate 110.

The local capping pattern 154 may include a silicon-containing insulating layer, a metal nitride layer, a metal oxynitride layer, an insulating layer doped with a metal or metal-doped insulating layer, or a combination thereof. In example embodiments, the local capping pattern 154 may include a silicon oxide layer, a silicon nitride layer, a silicon oxynitride (SiON) layer, a silicon carbonitride (SiCN) layer, a silicon oxycarbonitride (SiOCN) layer, a boron-containing silicon nitride (SiBN) layer, a titanium oxynitride (TiON) layer, TiN, TaN, a Ti-doped silicon oxide layer, a Ti-doped silicon nitride layer, or a combination thereof. However, a constituent material of the local capping pattern 154 may be varied.

The conductive plug 156 may include molybdenum (Mo), copper (Cu), tungsten (W), cobalt (Co), ruthenium (Ru), manganese (Mn), titanium (Ti), tantalum (Ta), aluminum, (Al), a combination thereof, etc.

In example embodiments, the local capping pattern 154 may be formed of the same material as that of at least a portion of the insulating structure that includes the insulating layer 149, the inter-gate insulating layer 148, and the insulating liner 146. For example, the local capping pattern 154, the inter-gate insulating layer 148, and the insulating layer 149 may each include a silicon oxide layer, and the local capping pattern 154 may include a portion in contact with at least one of the inter-gate insulating layer 148 and the insulating layer 149.

Referring to FIG. 2C, in the vertical direction (the Z direction), a first length L11 of the local capping pattern 154 may be about 30% to about 50% of a second length L12 of the source/drain contact hole CAH. In example embodiments, the first length L11 may be less than about 50% of the second length L12. For example, in the vertical direction (the Z direction), the first length L11 may be greater than about 30% and less than about 50% of the second length L12.

In forming the conductive plug 156, as a length (i.e., a length obtained by subtracting the first length L11 from the second length L12) of a portion of the inner sidewall of the source/drain contact hole CAH that is not covered with the local capping pattern 154 in a vertical direction (the Z direction) increases, a nucleation delay effect may increase at the exposed surfaces of the insulating layers that are exposed from inner sidewalls of the source/drain contact hole CAH (for example, the exposed surfaces of the insulating liner 146 and the inter-gate insulating layer 148), which may be advantageous for forming the conductive plug 156 in a bottom-up filling manner. When the local capping pattern 154 includes a metal, adhesion between the local capping pattern 154 and the conductive plug 156 may be improved.

In example embodiments, the local capping pattern 154 and the conductive plug 156 may each include a metal, and the metal included in the local capping pattern 154 may be different from the metal included in the conductive plug 156. For example, the metal included in the local capping pattern 154 may be formed of titanium (Ti), tantalum (Ta), or a combination thereof, and the metal included in the conductive plug 156 may be formed of molybdenum (Mo), copper (Cu), tungsten (W), cobalt (Co), ruthenium (Ru), aluminum (Al), or a combination thereof.

The conductive plug 156 may have a surface in contact with the metal silicide layer 152, a surface in contact with the insulating liner 146 and the inter-gate insulating layer 148, and a surface in contact with the local capping pattern 154.

In example embodiments, the conductive plug 156, the metal silicide layer 152, and the local capping pattern 154 may each include different metals. In other example embodiments, at least some of the conductive plug 156, the metal silicide layer 152, and the local capping pattern 154 may include the same metal. For example, each of the metal silicide layer 152 and the local capping pattern 154 may include a first metal, and the conductive plug 156 may not include the first metal.

Referring to FIGS. 2A and 2B, the top surface of each of the insulating layer 149 and the source/drain contact structures CA may be covered with an upper insulating structure 180. The upper insulating structure 180 may include an etch stop layer 182 and an interlayer insulating layer 184 sequentially stacked on the source/drain contact structures CA and the insulating layer 149. The etch stop layer 182 may be formed of silicon carbide (SiC), SiN, nitrogen-doped silicon carbide (SiC:N), SiOC, AlN, AlON, AlO, AlOC, or a combination thereof. The interlayer insulating layer 184 may include an oxide layer, a nitride layer, an ultra low-k (ULK) layer having an ultra low dielectric constant K of about 2.2 to about 2.4, or a combination thereof. For example, the interlayer insulating layer 184 may include a tetraethylorthosilicate (TEOS) film, a high density plasma (HDP) oxide layer, a boro-phospho-silicate glass (BPSG) layer, a flowable chemical vapor deposition (FCVD) oxide layer, an SiON layer, a SiN layer, a SiCOH layer, or a combination thereof.

A plurality of upper contact holes CAVH extending in the vertical direction (the Z direction) through the upper insulating structure 180 may be formed in the upper insulating structure 180. A plurality of via contacts CAV may be respectively disposed in the plurality of upper contact holes CAVH. Each of the via contacts CAV may contact the conductive plug 156 of the source/drain contact structure CA. The via contacts CAV may constitute an upper wiring structure.

The via contacts CAV may include a metal. In example embodiments, the via contacts CAV may include molybdenum (Mo), copper (Cu), tungsten (W), cobalt (Co), ruthenium (Ru), manganese (Mn), titanium (Ti), tantalum (Ta), aluminum (Al), a combination thereof, etc. For example, the via contacts CAV may be formed of Mo.

The metal included in the via contacts CAV may be formed of the same metal element as the metal included in the conductive plug 156. For example, each of the plurality of conductive plugs 156 and the via contacts CAV may include Mo. In other example embodiments, a metal included in the via contacts CAV and a metal included in the conductive plug 156 may be formed of different metal elements.

In example embodiments, a bottom surface of each of the via contacts CAV may contact a top surface of the conductive plug 156. Each of the via contacts CAV may be formed of an upper conductive plug directly in contact with the conductive plug 156 without passing through a separate conductive barrier layer. When the via contact CAV and the conductive plug 156 are formed of the same metal, an intermixing phenomenon (which may occur between metal elements thereof) may not affect electrical characteristics of the IC device 100. Therefore, a separate conductive barrier layer for blocking the intermixing may not be provided between the conductive plug 156 and the via contact CAV.

Referring to FIGS. 1 and 2B, a plurality of gate contact structures CB may be disposed on the gate lines GL. The gate contact structures CB may each be disposed in the gate contact hole CBH passing through the upper insulating structure 180, the insulating layer 149, and the insulating capping line 140. The gate contact structures CB may be disposed on the gate line GL, and may contact a top surface of at least one metal layer constituting the gate line GL. The gate lines GL may be connected to an upper conductive line through the gate contact structure CB.

Referring to FIGS. 2B and 2D, each of the gate contact structures CB may include a local capping pattern 194 and a conductive plug 196 in the gate contact hole CBH. The local capping pattern 194 may have an outer sidewall contacting an upper portion of an inner wall of the gate contact hole CBH and an inner sidewall facing the inside of the gate contact hole CBH, and may have a width gradually increasing in a horizontal direction, away from the substrate 110. The conductive plug 196 may pass through the insulating structure including the upper insulating structure 180, the insulating layer 149, and the insulating capping line 140 in a vertical direction (the Z direction) through the gate contact hole CBH. A lower sidewall of the conductive plug 196 may contact at least a portion of the insulating structure, e.g., the upper insulating structure 180 and the insulating layer 149. An upper sidewall of the conductive plug 196 may contact the local capping pattern 194. A top surface of the local capping pattern 194, a top surface of the conductive plug 196, and a top surface of the upper insulating structure 180 may extend in a horizontal direction on the same plane.

Referring to FIG. 2D, in the vertical direction (the Z direction), a first length L21 of the local capping pattern 194 may be about 30% to about 50% of a second length L22 of the gate contact hole CBH. In example embodiments, the first length L21 may be less than about 50% of the second length L22. For example, in the vertical direction (the Z direction), the first length L21 may be greater than about 30% and less than about 50% of the second length L22.

A more detailed configuration of the local capping pattern 194 and the conductive plug 196 is substantially the same as that described above for the local capping pattern 154 and the conductive plug 156 included in the source/drain contact structure CA.

Referring to FIG. 1, in the logic cell LC, a ground line VSS may be connected to the fin-type active region FA of the first device region RX1 through the source/drain contact structure CA in the first device region RX1, among the source/drain contact structures CA. A power line VDD may be connected to the fin-type active region FA of the second device region RX2 through the source/drain contact structure CA in the second device region RX2, among the source/drain contact structures CA. The ground line VSS and the power line VDD may be formed at a level higher than the top surface of each of the source/drain contact structures CA and the gate contact structures CB.

In example embodiments, the ground line VSS and the power line VDD may be formed of a local capping pattern for wiring and a conductive plug for wiring, respectively. The local capping pattern for wiring and the conductive plug for wiring respectively included in the ground line VSS and the power line VDD may have substantially the same configuration as that described above with respect to the local capping pattern 154 and the conductive plug 156 included in the source/drain contact structure CA.

In the IC device 100 illustrated in FIGS. 1 and 2A to 2D, the source/drain contact structures CA include the local capping pattern 154 and the conductive plug 156, and the gate contact structure CB includes the local capping pattern 194 and the conductive plug 196. The local capping patterns 154 and 194 surround outer sidewalls of the upper ends of the conductive plugs 156 and 196 and have a shape having a width gradually increasing in a horizontal direction away from the substrate 110, and thus, the local capping patterns 154 and 194 physically fix the conductive plugs 156 and 196 so that at least a portion of the conductive plugs 156 and 196 may not escape from a contact hole (e.g., the source/drain contact hole CAH or the gate contact hole CBH) during a manufacturing process of the IC device 100.

In particular, when the local capping patterns 154 and 194 include a metal, adhesion between the local capping patterns 154 and 194 and the conductive plugs 156 and 196 may be improved at a contact portion thereof, so that the effect of physically fixing the conductive plugs 156 and 196 by the local capping patterns 154 and 194 may be further improved. Also, when formed of an insulating material or a dielectric material, the local capping patterns 154 and 194 may provide a structure advantageous for securing an insulating distance between the conductive plugs 156 and 196 and a conductive region adjacent thereto, e.g., between the conductive plug 156 of the source/drain contact structure CA and the gate line GL adjacent thereto, compared to a case in which the local capping patterns 154 and 194 are formed of a conductive material.

In addition, without a separate barrier layer having a resistance, which is greater than that of the conductive plugs 156 and 196, between an insulating structure adjacent to the conductive plugs 156 and 196, i.e., an insulating structure including the insulating capping line 140, the insulating liner 146, the inter-gate insulating layer 148, and the insulating layer 149, and the conductive plugs 156 and 196, a lower sidewall of each of the conductive plugs 156 and 196 is in contact with the insulating structure. Accordingly, even when the IC device 100 has a device region having a reduced area due to down-scaling, the electrical characteristics and reliability of the IC device 100 may be improved, while contact resistance in each of the source/drain contact structure CA and the gate contact structure CB is reduced.

FIG. 2E is a cross-sectional view illustrating an IC device 100A according to other example embodiments. FIG. 2E illustrates a cross-sectional configuration of a region corresponding to the portion EX2 in FIG. 2B.

Referring to FIG. 2E, the IC device 100A may have substantially the same configuration as that of the IC device 100 described above with reference to FIGS. 1 and 2A to 2D. However, the IC device 100A may include an upper insulating structure 180A, instead of the upper insulating structure 180, and may include a gate contact structure CB2, instead of the gate contact structure CB.

The upper insulating structure 180A may include an etch stop layer 182 and an interlayer insulating layer 184A sequentially stacked on the insulating layer 149. The gate contact structure CB2 may be disposed in a gate contact hole CBHA passing through the upper insulating structure 180A, the insulating layer 149, and the insulating capping line 140.

The gate contact structure CB2 may include a local capping pattern 194A and a conductive plug 196 in the gate contact hole CBHA. The local capping pattern 194A may have an outer sidewall in contact with an upper portion of an inner wall of the gate contact hole CBHA and an inner sidewall facing the inside of the gate contact hole CBHA, and may have a width gradually increasing in a horizontal direction, away from the gate line GL.

The interlayer insulating layer 184A of the upper insulating structure 180A may include a round corner portion defining an upper portion of an entrance side of the gate contact hole CBHA. The local capping pattern 194A may have substantially the same configuration as that of the local capping pattern 194 described above with reference to FIGS. 2B and 2C. However, the local capping pattern 194A may be in contact with the round corner portion of the interlayer insulating layer 184A and may have an upper edge portion AR protruding in a radial direction away from the conductive plug 196 in a horizontal direction to correspond to a shape of the round corner portion.

In the IC device 100A, the round corner portion of the interlayer insulating layer 184A may be formed during a process of forming the gate contact hole CBHA. As the local capping pattern 194A is formed to be in contact with the round corner portion of the interlayer insulating layer 184A, the local capping pattern 194A may include the upper edge portion AR protruding in a radial direction away from the conductive plug 196 in a horizontal direction, as shown in FIG. 2E.

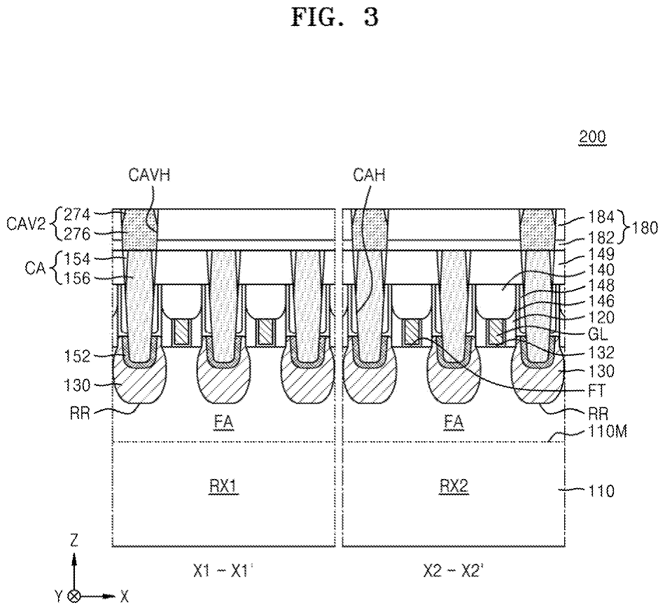

FIG. 3 is a cross-sectional view illustrating an IC device 200 according to still other example embodiments. FIG. 3 illustrates a cross-sectional configuration of the IC device 200 showing regions corresponding to a cross-section taken along line X1-X1′ and a cross-section taken along line X2-X2′ of FIG. 1. In FIG. 3, the same reference numerals as those of FIGS. 2A to 2C denote the same members, and redundant descriptions thereof are omitted herein.

Referring to FIG. 3, the IC device 200 may have substantially the same configuration as that of the IC device 100 described above with reference to FIGS. 1 and 2A to 2D. However, the IC device 200 includes a plurality of via contacts CAV2, instead of the via contacts CAV.

The via contacts CAV2 may each pass through the upper insulating structure 180, and may contact the conductive plug 156 of the source/drain contact structure CA. The via contacts CAV2 may constitute an upper wiring structure.

The via contacts CAV2 may include a local capping pattern 274 and a conductive plug 276 in the upper contact hole CAVH. In an example embodiment, the local capping pattern 274 may be referred to as an upper local capping pattern, and the conductive plug 276 may be referred to as an upper conductive plug.

The local capping pattern 274 may have an outer sidewall contacting an upper portion of an inner wall of the upper contact hole CAVH and an inner sidewall facing the inside of the upper contact hole CAVH, and may have a width gradually increasing in a horizontal direction, away from the substrate 110. The conductive plug 276 may pass through the insulating structure including the upper insulating structure 180 in a vertical direction (the Z direction) through the upper contact hole CAVH. A lower sidewall of the conductive plug 276 may contact at least a portion of the insulating structure, e.g., the etch stop layer 182 and the interlayer insulating layer 184. An upper sidewall of the conductive plug 276 may contact the local capping pattern 274. A top surface of the local capping pattern 274, a top surface of the conductive plug 276, and a top surface of the upper insulating structure 180 may extend in a horizontal direction on the same plane. Detailed configurations and effects of the local capping pattern 274 and the conductive plug 276 are substantially the same as those described above for the local capping pattern 154 and the conductive plug 156 with reference to FIGS. 2A and 2C.

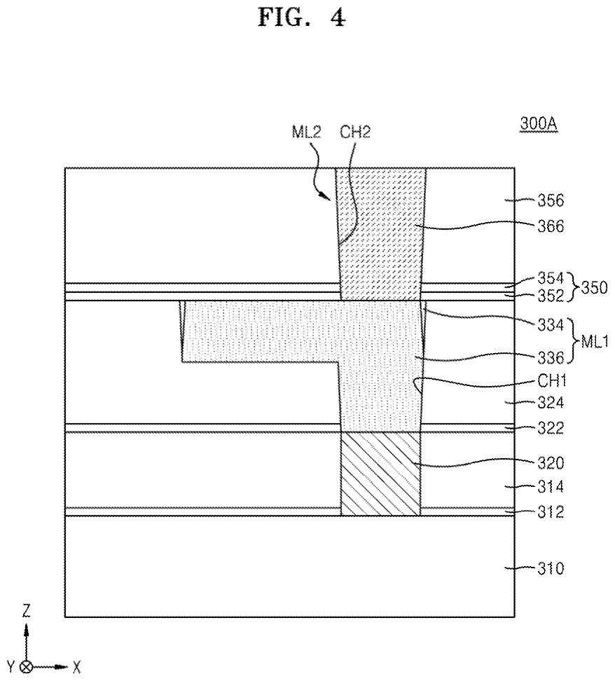

FIG. 4 is a cross-sectional view illustrating main components of an IC device 300A according to still other example embodiments.

Referring to FIG. 4, the IC device 300A may include a lower structure 310. The lower structure 310 may include a semiconductor substrate formed of an elemental semiconductor, such as Si or Ge, or a compound semiconductor, such as SiGe, SiC, GaAs, InAs, or InP. The lower structure 310 may include a conductive region (not shown). The conductive region may include a well that is doped with impurities, a structure that is doped with impurities, or a conductive layer. In example embodiments, the lower structure 310 may include circuit elements (not shown), such as a gate structure, an impurity region, and a contact plug. For example, the lower structure 310 may include the structures described for the IC device 100 with reference to FIGS. 2A to 2C or the structures described for the IC device 200 with reference to FIG. 3.

A lower wiring structure 320 may be disposed on the lower structure 310. The lower wiring structure 320 may contact the lower structure 310 through the first etch stop layer 312 and the lower insulating layer 314 sequentially stacked on the lower structure 310.

The first etch stop layer 312 may be formed of a material having an etch selectivity different from that of the lower insulating layer 314. In example embodiments, the first etch stop layer 312 may include a silicon nitride layer, a carbon-doped silicon nitride layer, or a carbon-doped silicon oxynitride layer. In other example embodiments, the first etch stop layer 312 may include a metal nitride layer, e.g., an AlN layer.

In example embodiments, the lower insulating layer 314 may include a silicon oxide layer. For example, the lower insulating layer 314 may be formed of a silicon oxide-based material such as plasma enhanced oxide (PEOX), tetraethyl orthosilicate (TEOS), boro TEOS (BTEOS), phosphorous TEOS (PTEOS), boro phospho TEOS (BPTEOS), boro silicate glass (BSG), phospho silicate glass (PSG), boro phospho silicate glass (BPSG), etc. In other example embodiments, the lower insulating layer 314 may include a low dielectric film having a low dielectric constant K of about 2.2 to about 3.0, e.g., a SiOC film or a SiCOH film.

The lower wiring structure 320 may include a metal layer and a conductive barrier layer surrounding the metal layer. The metal layer may be formed of Mo, Cu, W, Al, or Co. The conductive barrier layer may be formed of Ti, Ta, W, TiN, TaN, WN, WCN, TiSiN, TaSiN, WSiN, or a combination thereof. In example embodiments, the lower wiring structure 320 may be electrically connected to a conductive region formed in the lower structure 310. In other example embodiments, the lower wiring structure 320 may be connected to a source/drain region (not shown) or a gate electrode (not shown) of a transistor formed in the lower structure 310.

A second etch stop layer 322 and a first insulating layer 324 may be sequentially disposed on the lower insulating layer 314. A first metal wiring structure ML1 may extend to the lower wiring structure 320 through an insulating structure including the first insulating layer 324 and the second etch stop layer 322.

The first metal wiring structure ML1 may include a local capping pattern 334 and a lower conductive line 336 in the lower contact hole CH1. The lower conductive line 336 of the first metal wiring structure ML1 may include a plug shape portion adjacent to the lower wiring structure 320, and a line shape portion integrally connected to plug shape portion and spaced apart from the lower local capping pattern 334 with the plug shape portion therebetween.

The local capping pattern 334 of the first metal wiring structure ML1 may have an outer sidewall contacting an upper portion of an inner wall of the lower contact hole CH1 and an inner sidewall facing the inside of the lower contact hole CH1, and may have a width gradually increasing in a horizontal direction, away from the lower wiring structure 320. The lower conductive line 336 may pass through an insulating structure including the second etch stop layer 322 and the first insulating layer 324 in a vertical direction (the Z direction) through the lower contact hole CH1. A lower surface of the lower conductive line 336 may contact at least a portion of the insulating structure, e.g., the upper insulating structure 180 and the insulating layer 149. A top surface of the lower conductive line 336 may contact the local capping pattern 334. A top surface of the local capping pattern 334, a top surface of the lower conductive line 336, and a top surface of the first insulating layer 324 may extend in a horizontal direction on the same plane. A more detailed configuration and effect of the local capping pattern 334 and the lower conductive line 336 are substantially the same as those of the local capping pattern 154 and the conductive plug 156 described above with reference to FIGS. 2A and 2C.

The IC device 300A may include an insulating capping layer 350 covering a top surface of each of the first metal wiring structure ML1 and the first insulating layer 324. In example embodiments, the insulating capping layer 350 may have a multi-layer structure including a first insulating capping layer 352 including metal and a second insulating capping layer 354 including no metal. In example embodiments, the first insulating capping layer 352 may be formed of AN, AlON, AlO, or AlOC, and the second insulating capping layer 354 may be formed of silicon carbide (SiC), silicon nitride (SiN), or nitrogen-doped silicon carbide (SiC:N), or SiOC, for example. In example embodiments, in the insulating capping layer 350, any one of the first insulating capping layer 352 and the second insulating capping layer 354 may be omitted.

The insulating capping layer 350 may be covered with a second insulating layer 356. A second metal wiring structure ML2 may be disposed in an upper contact hole CH2 passing through the insulating structure including the insulating capping layer 350 and the second insulating layer 356. The second metal wiring structure ML2 may be connected to the first metal wiring structure ML1. Constituent materials of the first insulating layer 324 and the second insulating layer 356 may be substantially the same as those of the lower insulating layer 314 described above.

The second metal wiring structure ML2 may contact a top surface of the lower conductive line 336. The second metal wiring structure ML2 may include an upper wiring 366 directly contacting the lower conductive line 336 of the first metal wiring structure ML1 without passing through a separate barrier layer. In example embodiments, the upper wiring 366 may be formed of a metal including an element selected from molybdenum (Mo), copper (Cu), tungsten (W), cobalt (Co), ruthenium (Ru), manganese (Mn), titanium (Ti), tantalum (Ta), and aluminum (Al) alone, or a metal including a combination thereof. In example embodiments, the lower conductive line 336 of the first metal wiring structure ML1 and the upper wiring 366 of the second metal wiring structure ML2 may include the same metal. For example, each of the lower conductive line 336 of the first metal wiring structure ML1 and the upper wiring 366 of the second metal wiring structure ML2 may be formed of Mo.

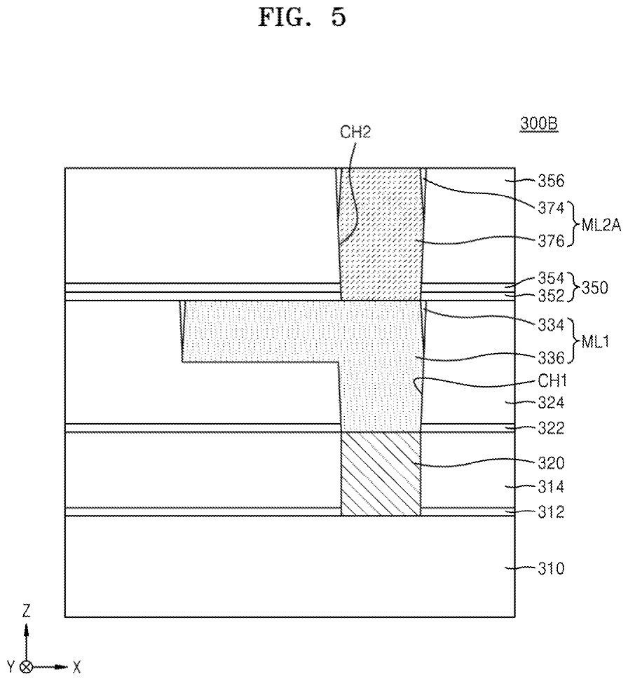

FIG. 5 is a cross-sectional view illustrating an IC device 300B according to still other example embodiments. In FIG. 5, the same reference numerals as those of FIG. 4 denote the same members, and a redundant description thereof is omitted herein.

Referring to FIG. 5, the IC device 300B may have substantially the same configuration as that of the IC device 300A described above with reference to FIG. 4. However, the IC device 300B includes a second metal wiring structure ML2A instead of the second metal wiring structure ML2.

The second metal wiring structure ML2A may be connected to the first metal wiring structure ML1 through the insulating structure including the insulating capping layer 350 and the second insulating layer 356. The second metal wiring structure ML2A may constitute an upper wiring structure.

The second metal wiring structure ML2A may include a local capping pattern 374 and an upper conductive line 376 in the upper contact hole CH2. A bottom surface of the upper conductive line 376 of the second metal wiring structure ML2A may contact a top surface of the lower conductive line 336.

The local capping pattern 374 of the second metal wiring structure ML2A may have an outer sidewall contacting an upper portion of the inner wall of the upper contact hole CH2, may have an inner sidewall facing the inside of the upper contact hole CH2, and may have a width gradually increasing in a horizontal direction, away from the lower wiring structure 320. The upper conductive line 376 may pass through the insulating structure including the insulating capping layer 350 and the second insulating layer 356 in a vertical direction (the Z direction) through the upper contact hole CH2. A lower surface of the upper conductive line 376 may contact at least a portion of the insulating structure, e.g., the insulating capping layer 350 and the second insulating layer 356. A top surface of the upper conductive line 376 may contact the local capping pattern 374. A top surface of the local capping pattern 374, a top surface of the upper conductive line 376, and a top surface of the second insulating layer 356 may extend in a horizontal direction on the same plane. A more detailed configuration and effect of the local capping pattern 374 and the upper conductive line 376 are substantially the same as those of the local capping pattern 154 and the conductive plug 156 included in the source/drain contact structure CA described above with reference to FIGS. 2A and 2C.

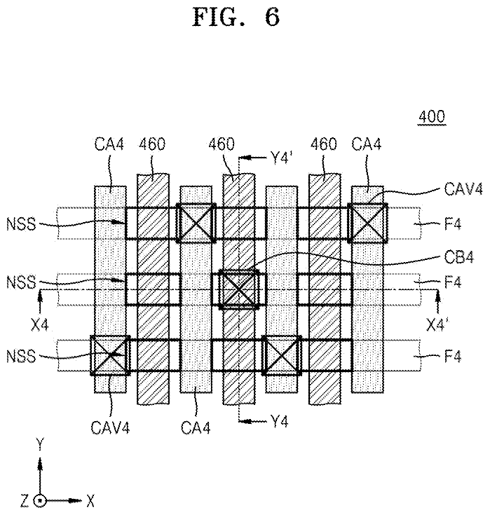

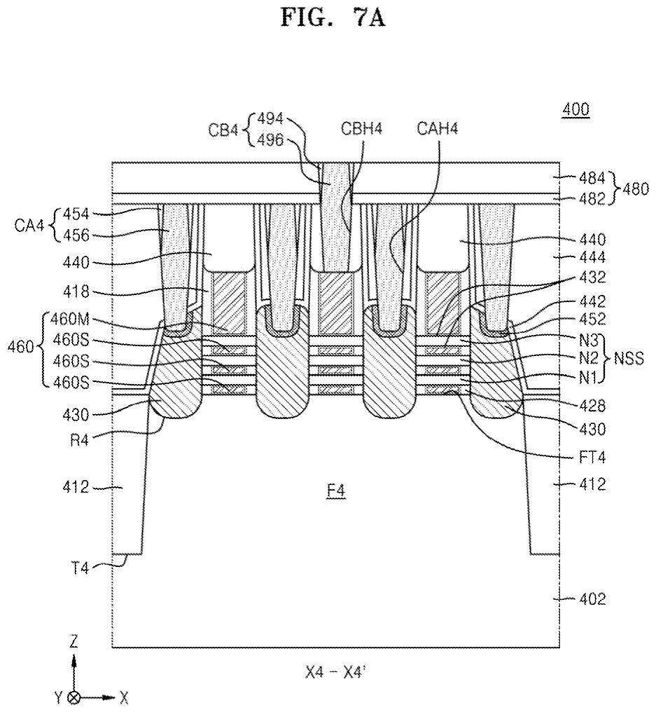

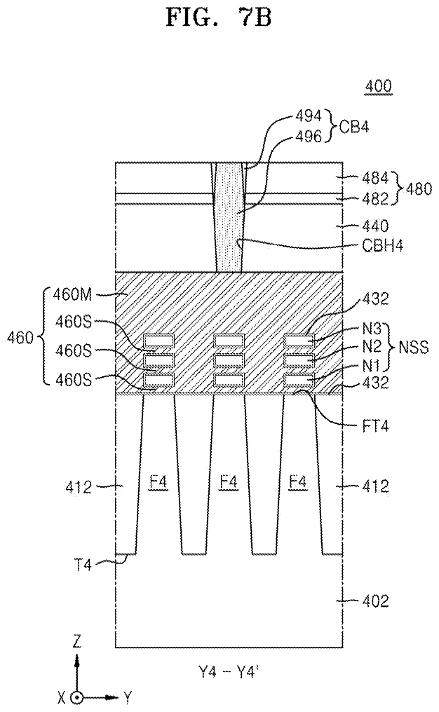

FIG. 6 is a plan layout diagram of some components of an IC device 400 according to still other example embodiments, FIG. 7A is a cross-sectional view taken along line X4-X4′ of FIG. 6, and FIG. 7B is a cross-sectional view taken along line Y4-Y4′ of FIG. 6. An example configuration of the IC device 400 including a multi-bridge channel field effect transistor (MBCFET) or a gate-all-around FET (GAAFET) device is described with reference to FIGS. 6, 7A, and 7B.

Referring to FIGS. 6, 7A, and 7B, the IC device 400 may include a plurality of fin-type active regions F4 protruding from a substrate 402 and elongated in a first horizontal direction (the X direction), and a plurality of nanosheet stacks NSS facing a top surface FT4 of the fin-type active regions F4 at a position apart upward from the fin-type active regions F4 in a vertical direction (the Z direction). As used herein, the term “nanosheet” refers to a conductive structure having a cross-section substantially perpendicular to a direction in which current flows. It should be understood that the nanosheet may include nanowires.

A trench T4 defining fin-type active regions F4 may be formed in the substrate 402, and the trench T4 may be filled with a device separation layer 412. The substrate 402, the fin-type active regions F4, and the device separation layer 412 may have substantially the same configuration as those of the substrate 110, the fin-type active region FA, and the device separation layer 112 described above with reference to FIGS. 2A to 2C.

A plurality of gate lines 460 may extend in a second horizontal direction (the X direction) on the fin-type active regions F4. The nanosheet stacks NSS may be disposed on the top surface FT4 of each of the fin-type active regions F4 in regions in which the fin-type active regions F4 intersect the gate lines 460, and may face the top surface FT4 of the fin-type active region F4 at a position apart from the active region F4. A plurality of nanosheet transistors may be formed in portions in which the fin-type active regions F4 intersect the gate lines 460 on the substrate 402.

The nanosheet stacks NSS may each include a plurality of nanosheets N1, N2, and N3 overlapping each other in a vertical direction (the Z direction) on the top surface FT4 of the fin-type active region F4. The nanosheets N1, N2, and N3 may include a first nanosheet N1, a second nanosheet N2, and a third nanosheet N3 having different vertical distances from the top surface FT4 of the fin-type active region F4.

FIG. 6 illustrates a case in which a planar shape of the nanosheet stack NSS has a substantially quadrangular shape, as an example, but the nanosheet stack NSS may have various planar shapes depending on a planar shape of each of the fin-type active region F4 and the gate line 460. In the present example, a configuration in which the nanosheet stacks NSS and the gate lines 460 are formed on one fin-type active region F4 and the nanosheet stacks NSS are formed in a row in a first horizontal direction (the X direction) on one fin-type active region F4 is illustrated, but the number of nanosheet stacks NSS disposed on one fin-type active region F4 may be varied. For example, one nanosheet stack NSS may be formed on one fin-type active region F4. In this example, a case in which the nanosheet stacks NSS each include three nanosheets is illustrated, but the nanosheet stack NSS may include one or more nanosheets, and the number of nanosheets constituting the nanosheet stack NSS may be varied.

Each of the nanosheets N1, N2, and N3 may have a channel region. In example embodiments, each of the nanosheets N1, N2, and N3 may be formed of a Si layer, a SiGe layer, or a combination thereof.

A plurality of recess regions R4 may be formed at an upper portion of the fin-type active region F4, and a plurality of source/drain regions 430 may be disposed on the recess regions R4. The source/drain regions 430 may be formed of an epitaxial semiconductor layer. Referring to FIG. 7A, among the source/drain regions 430, the source/drain region 430 adjacent to the device separation layer 412 may have a smaller volume, compared with the source/drain region 430 relatively far from the device separation layer 412. A more detailed configuration of the source/drain regions 430 is substantially the same as that of the source/drain regions 130 described above with reference to FIGS. 2A and 2C.

The gate line 460 may surround each of the nanosheets N1, N2, and N3, while covering the nanosheet stack NSS on the fin-type active region F4. The gate lines 460 may each include a main gate portion 460M covering an upper surface of each of the nanosheet stacks NSS and elongated in a second horizontal direction (the Y direction), and a plurality of sub-gate portions 460S integrally connected to the main gate portion 460M and disposed between each of the nanosheets N1, N2, and N3 and between the fin-type active region F4 and the first nanosheet N1 one by one. The nanosheets N1, N2, and N3 may have a gate-all-around (GAA) structure surrounded by the gate line 460. The gate line 460 may be formed of a metal, a metal nitride, a metal carbide, or a combination thereof. The metal may be selected from Ti, W, Ru, Nb, Mo, Hf, Ni, Co, Pt, Yb, Tb, Dy, Er, and Pd. The metal nitride may be selected from TiN and TaN. The metal carbide may be TiAlC. A gate insulating layer 432 may be between the nanosheet stack NSS and the gate line 460. The gate insulating layer 432 may have substantially the same configuration as that of the gate insulating layer 132 described above with reference to FIGS. 2A to 2C.

A metal silicide layer 452 may be formed on a top surface of each of the source/drain regions 430. The metal silicide layer 452 may have substantially the same configuration as that of the metal silicide layer 152 described above with reference to FIGS. 2A and 2C.

Both sidewalls of each of the gate lines 460 may be covered with a plurality of outer insulating spacers 418. The outer insulating spacers 418 may cover both sidewalls of the main gate portion 460M on the nanosheet stacks NSS. The outer insulating spacers 418 and the source/drain regions 430 may be covered with an insulating liner 442. The outer insulating spacer 418 and the insulating liner 442 may each be formed of SiN, SiCN, SiBN, SiON, SiOCN, SiBCN, SiOC, SiO₂, or a combination thereof. The insulating liner 442 may be omitted.

A plurality of inner insulating spacers 428 may be interposed between each of the nanosheets N1, N2, and N3 and between the fin-type active region F4 and the first nanosheet N1. Both sidewalls of each of the sub-gate portions 460S may be covered with an inner insulating spacer 428 with the gate insulating layer 432 therebetween. The inner insulating spacers 428 may be between the sub-gate portions 460S and the source/drain regions 430. In example embodiments, the outer insulating spacer 418 and the inner insulating spacer 428 may be formed of the same insulating material. In other example embodiments, the outer insulating spacer 418 and the inner insulating spacer 428 may be formed of different insulating materials. The inner insulating spacer 428 may be formed of SiN, SiCN, SiBN, SiON, SiOCN, SiBCN, SiOC, SiO₂, or a combination thereof. The inner insulating spacer 428 may further include an air gap. In example embodiments, the inner insulating spacers 428 may be omitted. In this case, each of the source/drain regions 430 may contact the gate insulating layer 432 between the source/drain region 430 and the sub-gate portion 460S.

The insulating liner 442 may be covered with an inter-gate insulating layer 444. The inter-gate insulating layer 444 may include a silicon oxide layer. A plurality of source/drain contact structures CA4 may be disposed in source/drain contact holes CAH4 passing through the inter-gate insulating layer 444 and the insulating liner 442. Each of the source/drain contact structures CA4 may be configured to be connected to the source/drain region 430 through the metal silicide layer 452. Each of the source/drain contact structures CA4 may include a local capping pattern 454 and a conductive plug 456.

The conductive plug 456 may be elongated in a vertical direction (the Z direction) through the inter-gate insulating layer 444 and the insulating liner 442. The local capping pattern 454 may be disposed concentrically with the conductive plug 456, and may have a width gradually increasing in a horizontal direction away from the substrate 402. The conductive plug 456 may pass through the insulating structure including the inter-gate insulating layer 444 and the insulating liner 442 in a vertical direction (the Z direction). A lower sidewall of the conductive plug 456 may contact at least a portion of the insulating structure, e.g., the inter-gate insulating layer 444 and the insulating liner 442. An upper sidewall of the conductive plug 456 may contact the local capping pattern 454. A top surface of the local capping pattern 454, a top surface of the conductive plug 456, and a top surface of the inter-gate insulating layer 444 may extend in a horizontal direction on the same plane. A more detailed configuration and effect of the local capping pattern 454 and the conductive plug 456 are the same as those of the local capping pattern 154 and the conductive plug 156 included in the source/drain contact structure CA described above with reference to FIGS. 2A and 2C.

Each of the gate lines 460 may be covered with an insulating capping line 440. The insulating capping line 440 may have substantially the same configuration as that of the insulating capping line 140 described above with reference to FIGS. 2A to 2C.

The IC device 400 may include an upper insulating structure 480 covering a top surface of each of a plurality of source/drain contact structures CA4, a plurality of insulating capping lines 440, and the inter-gate insulating layer 444. The upper insulating structure 480 may include an etch stop layer 482 and an interlayer insulating layer 484 sequentially stacked on the source/drain contact structure CA4 and the insulating capping line 440. The etch stop layer 482 and the interlayer insulating layer 484 may have substantially the same configuration as those of the etch stop layer 182 and the interlayer insulating layer 184 described above with reference to FIGS. 2A and 2B.

Referring to FIG. 6, a plurality of via contacts CAV4 may be disposed on the source/drain contact structures CA4. The via contacts CAV4 may each pass through the upper insulating structure 480 to contact a top surface of the source/drain contact structure CA4. In example embodiments, each of the via contacts CAV4 may have the same configuration as that of the via contacts CAV described above with reference to FIG. 2A. In other example embodiments, each of the via contacts CAV4 may have the same configuration as that of the via contacts CAV2 described above with reference to FIG. 3.

Referring to FIGS. 6, 7A, and 7B, a gate contact structure CB4 may be disposed on the gate line 460. The gate contact structure CB4 may be configured to be disposed in a gate contact hole CBH4 passing through the upper insulating structure 480 and the insulating capping line 440 in a vertical direction (the Z direction) and connected to a top surface of the gate line 460.

The gate contact structure CB4 may be disposed on the gate line 460, and may be in contact with a top surface of at least one metal layer constituting the gate line 460. The gate lines 460 may be connected to an upper conductive line through a gate contact structure CB4.

The gate contact structure CB4 may include a local capping pattern 494 and a conductive plug 496 in the gate contact hole CBH4. The local capping pattern 494 may have an outer sidewall in contact with an upper portion of an inner wall of the gate contact hole CBH4, may have an inner sidewall facing the inside of the gate contact hole CBH4, and may have a width gradually increasing in a horizontal direction, away from the substrate 402. The conductive plug 496 may pass through the insulating structure including the insulating capping line 440 and the upper insulating structure 480 in a vertical direction (the Z direction) through the gate contact hole CBH4. A lower sidewall of the conductive plug 496 may contact at least a portion of the insulating structure, e.g., the insulating capping line 440. An upper sidewall of the conductive plug 496 may contact the local capping pattern 494. A top surface of the local capping pattern 494, a top surface of the conductive plug 496, and a top surface of the upper insulating structure 480 may extend in a horizontal direction on the same plane. A more detailed configuration and effect of the local capping pattern 494 and the conductive plug 496 are substantially the same as those of the local capping pattern 154 and the conductive plug 156 included in the source/drain contact structure CA described above with reference to FIGS. 2A and 2B.

In the IC device 400 described above with reference to FIGS. 6, 7A, and 7B, the source/drain contact structure CA4 includes the local capping pattern 454 and the conductive plug 456, and the gate contact structure CB4 includes the local capping pattern 494 and the conductive plug 496.

The local capping patterns 454 and 494 surround the outer sidewalls of the upper ends of the conductive plugs 456 and 496, and have a width gradually increasing in a horizontal direction, away from the substrate 402. Thus, the local capping patterns 454 and 494 may physically fix the conductive plugs 456 and 496 so that at least a portion of the conductive plugs 456 and 496 may not escape from the contact hole (e.g., the source/drain contact hole CAH4 or the gate contact hole CBH4).

In particular, when the local capping patterns 454 and 494 include a metal, adhesion between the local capping patterns 454 and 494 and the conductive plugs 456 and 496 may be improved at a contact portion thereof, so that the effect of physically fixing the conductive plugs 456 and 496 by the local capping patterns 454 and 494 may be further improved. In addition, when formed of an insulating material or a dielectric material, the local capping patterns 454 and 494 may provide a structure advantageous for securing an insulating distance between the conductive plugs 456 and 496 and a conductive region adjacent thereto, e.g., between the conductive plug 456 of the source/drain contact structure CA4 and the gate line 460 and/or the conductive plug 496 adjacent thereto, compared to a case in which the local capping patterns 454 and 494 are formed of a conductive material.

In addition, without a separate barrier layer having resistance, which is greater than that of the conductive plugs 456 and 496, between an insulating structure adjacent to the conductive plugs 456 and 496, i.e., an insulating structure including the insulating capping line 440, the insulating liner 442, the inter-gate insulating layer 444, and the upper insulating structure 480, and the conductive plugs 456 and 496, a lower sidewall of each of the conductive plugs 456 and 496 is in contact with the insulating structure. Accordingly, even when the IC device 400 has a device region having a reduced area due to down-scaling, the electrical characteristics and reliability of the IC device 400 may be improved, while contact resistance in each of the source/drain contact structure CA4 and the gate contact structure CB4 is reduced.

Hereinafter, a method of manufacturing an IC device, according to example embodiments, is described in detail.

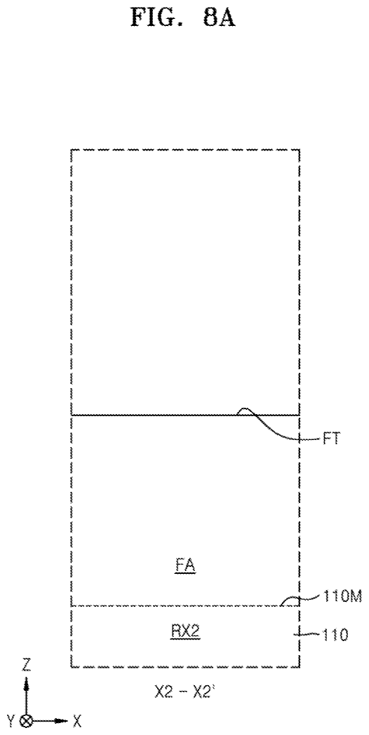

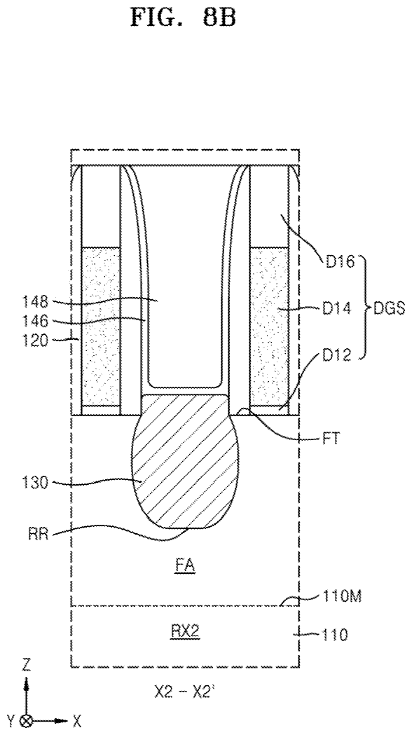

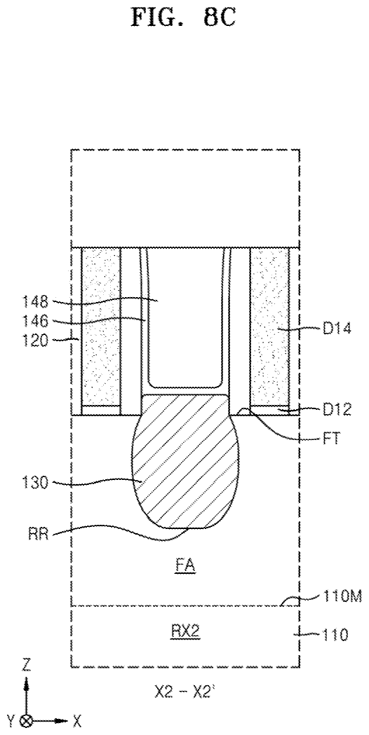

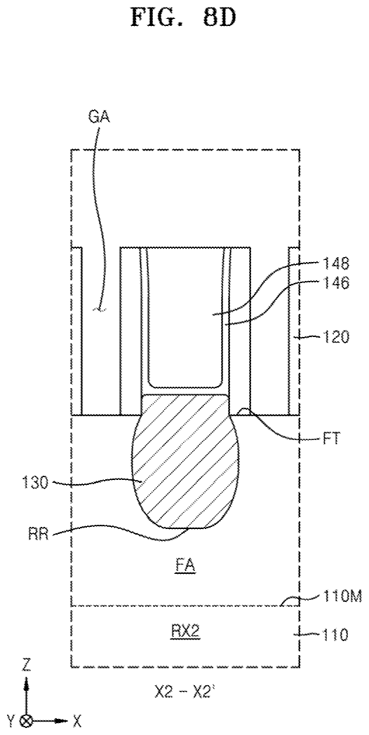

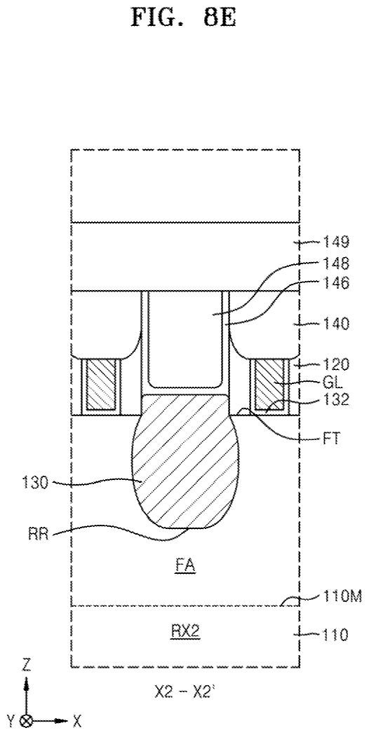

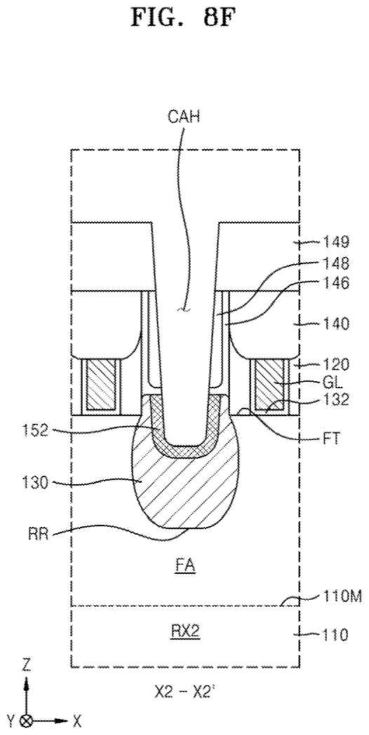

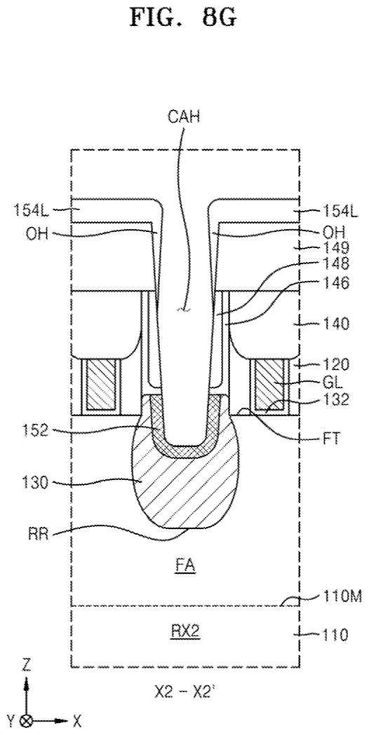

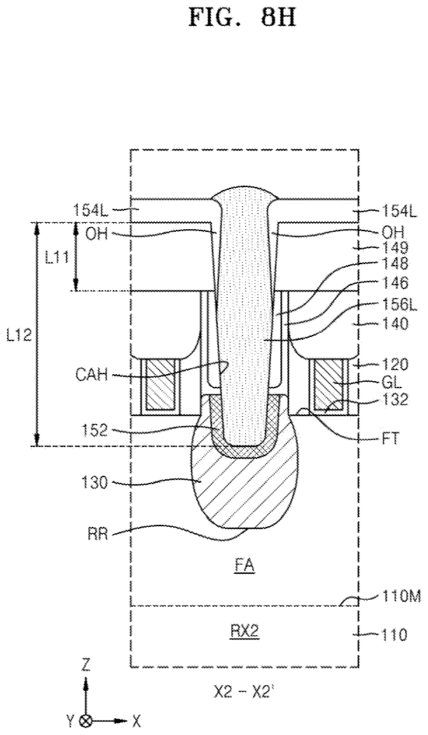

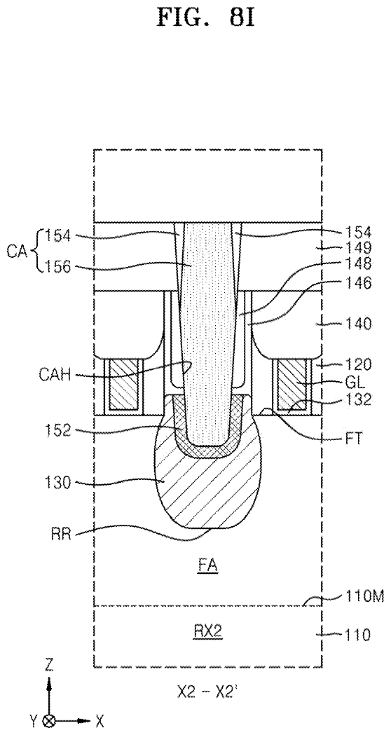

FIGS. 8A to 8I are cross-sectional views illustrating a process sequence of a method of manufacturing an IC device, according to example embodiments, and are cross-sectional views according to a process sequence of a partial region of portions corresponding to a cross-section taken along line X2-X2′ of FIG. 1. A method of manufacturing the IC device 100 illustrated in FIGS. 1 and 2A to 2D is described with reference to FIGS. 8A to 8I. FIGS. 8A to 8I illustrate a process sequence in a partial region of the second device region RX2, but the same or similar processes as described below may also be performed on the first device region RX1. In FIGS. 8A to 8I, the same reference numerals as those in FIGS. 1 and 2A to 2D denote the same members, and redundant descriptions thereof are omitted herein.

Referring to FIG. 8A, a partial region of the substrate 110 may be etched in the first device region RX1 and the second device region RX2 (see FIGS. 1 and 2A) to form fin-type active regions FA protruding from the main surface 110M of the substrate 110 upward in a vertical direction (the Z direction) and extending in parallel to each other in the first horizontal direction (the X direction). A device separation layer 112 (see FIG. 2B) covering both lower sidewalls of each of the fin-type active regions FA may be formed. Thereafter, a portion of the device separation layer 112 and a portion of the substrate 110 may be etched to form a deep trench DT (see FIG. 2B) defining the first device region RX1 and the second device region RX2. The deep trench DT may be filled with the inter-device separation insulating layer 114. Referring to FIG. 2B, after the deep trench DT in the device separation region DTA is filled with the inter-device separation insulating layer 114, a structure in which the fin-type active regions FA protrude above the top surface of the device separation layer 112 in the first device region RX1 and the second device region RX2 may be obtained.

Referring to FIG. 8B, a plurality of dummy gate structures DGS extending across the fin-type active regions FA may be formed on the device separation layer 112 and the inter-device separation insulating layer 114 (see FIG. 2B). The dummy gate structures DGS may include a dummy gate insulating layer D12, a dummy gate line D14, and a dummy insulating capping layer D16 sequentially stacked on the fin top surface FT of the fin-type active regions FA, and on each of the device separation layer 112 and the inter-device separation insulating layer 114 (see FIG. 2B). The dummy gate insulating layer D12 may include a silicon oxide layer. The dummy gate line D14 may include a polysilicon layer. The dummy insulating capping layer D16 may include a silicon nitride layer.

Insulating spacers 120 may be formed on both sidewalls of the dummy gate structure DGS. Portions of the fin-type active regions FA exposed between each of the dummy gate structures DGS may be etched to form the recess region RR in the fin-type active regions.

Thereafter, the source/drain region 130 may be formed to fill the recess regions RR in the first device region RX1 and the second device region RX2. In example embodiments, a low-pressure chemical vapor deposition (LPCVD) process, a selective epitaxial growth (SEG) process, or a cyclic deposition and etching (CDE) process may be performed using source materials including an elemental semiconductor precursor to form the source/drain region 130. In example embodiments, silane (SiH₄), disilane (Si₂H₆), trisilane (Si₃H₈), dichlorosilane (SiH₂Cl₂), etc., may be used as a Si source to form the source/drain region 130 formed of a Si layer doped with an n-type dopant. The n-type dopant may be selected from phosphorus (P), arsenic (As), and antimony (Sb). In other example embodiments, a Si source and a Ge source may be used to form the source/drain region 130 including a SiGe layer doped with a p-type dopant. As the Si source, silane (SiH₄), disilane (Si₂H₆), trisilane (Si₃H₈), dichlorosilane (SiH₂Cl₂), or the like may be used. As the Ge source, germane (GeH₄), digermane (Ge₂H₆), trigermane (Ge₃H₈), tetragermane (Ge₄H₁₀), dichlorogermane (GeH₂Cl₂), etc., may be used. The p-type dopant may be selected from boron (B) and gallium (Ga).

The process of forming the source/drain region 130 in the first device region RX1 and the process of forming the source/drain region 130 in the second device region RX2 may be sequentially performed. For example, after the source/drain region 130 is formed in the first device region RX1, the source/drain region 130 may be formed in the second device region RX2, or after the source/drain region 130 is formed in the second device region RX2, the source/drain region 130 may be formed in the first device region RX1.

The insulating liner 146 and the inter-gate insulating layer 148 sequentially covering a resultant structure, in which the source/drain region 130 is formed in the first device region RX1 and the second device region RX2, may be formed. The inter-gate insulating layer 148 may be formed to have a planarized top surface. After the inter-gate insulating layer 148 is formed, a top surface of the dummy insulating capping layer D16 may be exposed.

Referring to FIG. 8C, in the result of FIG. 8B, the dummy insulating capping layer D16 and surrounding insulating layers may be removed from the result structure of FIG. 8B by a chemical mechanical polishing (CMP) process to expose a top surface of the dummy gate line D14. As a result, heights of the insulating liner 146, the inter-gate insulating layer 148, and the insulating spacers 120 may be lowered.

Referring to FIG. 8D, the gate spaces GA may be prepared by removing the dummy gate lines D14 and the dummy gate insulating layers D12 from a resultant structure of FIG. 8C. The insulating spacer 120, the fin-type active regions FA, the device separation layer 112, and the inter-device separation insulating layer 114 (see FIG. 2B) may be exposed through the gate spaces GA.

Referring to FIG. 8E, in the result ant structure of FIG. 8D, a gate insulating layer 132, a gate line GL, and an insulating capping line 140 may be formed in the gate spaces GA.

In order to form the gate insulating layer 132, the gate line GL, and the insulating capping line 140, first, the gate insulating layers 132 and gate lines GL filling the gate spaces GA may be formed and then etched back so that the gate insulating layers 132 and the gate lines GL may fill only a lower portion of each of the gate spaces GA. During the etch-back, an upper portion of the insulating spacer 120 may also be removed to lower the height of the insulating spacer 120.

Thereafter, the insulating capping line 140 covering the top surface of each of the gate line GL, the gate insulating layer 132, and the insulating spacer 120 in the gate spaces GA and filling an upper portion of the gate space GA may be formed. The insulating capping line 140 may be formed to have a planarized top surface. During the planarization of the top surface of the insulating capping line 140, an upper portion of each of the insulating liner 146 and the inter-gate insulating layer 148 may also be removed so that the heights thereof may be lowered. Thereafter, the insulating layer 149 covering the top surface of each of the insulating capping line 140, the insulating liner 146, and the inter-gate insulating layer 148 may be formed.

In example embodiments, before forming the gate insulating layer 132, an interface layer (not shown) may be formed to cover the surface of each of the fin-type active regions FA exposed through the gate spaces GA. A portion of the fin-type active regions FA exposed in the gate spaces GA may be oxidized to form the interface layer.

Referring to FIG. 8F, the source/drain contact hole CAH passing through the insulating layer 149 and the inter-gate insulating layer 148 to expose the source/drain regions 130 may be formed in a resultant structure of FIG. 8E. After the source/drain regions 130 are exposed through the source/drain contact holes CAH, a partial region of the source/drain region 130 may be removed through the source/drain contact holes CAH so that the source/drain contact hole CAH may be further elongated toward the substrate 110. In example embodiments, an anisotropic etching process for forming the source/drain contact hole CAH may be performed using plasma.

After the source/drain contact hole CAH is formed, a metal silicide layer 152 may be formed on the source/drain region 130 exposed from a bottom side of the source/drain contact hole CAH. In example embodiments, in order to form the metal silicide layer 152, a metal liner (not shown) conformally covering an inner wall of the source/drain contact hole CAH may be formed and heat treated to induce a reaction between the source/drain region 130 and a metal constituting the metal liner. After the metal silicide layer 152 is formed, a remaining portion of the metal liner may be removed. A portion of the source/drain region 130 may be consumed during the process of forming the metal silicide layer 152. In example embodiments, when the metal silicide layer 152 is formed of a titanium silicide layer, the metal liner may be formed of a Ti layer.

Referring to FIG. 8G, in a resultant structure of FIG. 8F, a local capping layer 154L covering an upper portion of the inner sidewall of each of the source/drain contact hole CAH and a top surface of the insulating layer 149 may be formed.

In forming the local capping layer 154L, the local capping layer 154L may be formed with a degraded step coverage, rather than being conformally formed on the insulating layers defining the inner wall of the source/drain contact hole CAH, e.g., on the inter-gate insulating layer 148 and the insulating layer 149.

In example embodiments, a physical vapor deposition (PVD) process may be used to form the local capping layer 154L. Here, the local capping layer 154L may be controlled to include an overhang portion (OH) covering only an upper portion, which is adjacent to an entrance, of the inner wall of the source/drain contact hole CAH by controlling a deposition atmosphere for forming the local capping layer 154L, e.g., a bias applied to the substrate, temperature, pressure, plasma formation conditions, etc., or by controlling a flow rate of source gases considering a sticking coefficient of each of atoms to constitute the local capping layer 154L. The local capping layer 154L may be formed to cover only an upper portion of the insulating layers defining the source/drain contact hole CAH in the source/drain contact hole CAH. For example, the local capping layer 154L may be formed to cover a portion of the sidewall of the insulating layer 149 exposed in the source/drain contact hole CAH and a portion of the sidewall of the inter-gate insulating layer 148.

The local capping layer 154L in the source/drain contact hole CAH may cover the insulating structure including the insulating layer 149 and the inter-gate insulating layer 148 with a greater thickness in a direction away from the substrate 110. A horizontal width of a portion defined by the local capping layer 154L in the source/drain contact hole CAH may gradually decrease in a direction away from the substrate 110.

The local capping layer 154L may include a silicon-containing insulating layer, a metal nitride layer, a metal oxynitride layer, an insulating layer doped with a metal, or a combination thereof In example embodiments, the local capping layer 154L may include a silicon oxide layer, a silicon nitride layer, a silicon oxynitride (SiON) layer, a silicon carbonitride (SiCN) layer, a silicon oxycarbonitride (SiOCN) layer, a boron-containing silicon nitride (SiBN) layer, a titanium oxynitride (TiON) layer, TiN, TaN, a Ti-doped silicon oxide layer, a Ti-doped silicon nitride layer, or a combination thereof. However, the constituent material of the local capping layer 154L may be varied.

Referring to FIG. 8H, in the resultant structure of FIG. 8G, a metal-containing layer 156L may be formed to fill the source/drain contact hole CAH. The metal-containing layer 156L may have a surface in contact with the local capping layer 154L inside the source/drain contact hole CAH.

The metal-containing layer 156L may include a metal selected from molybdenum (Mo), copper (Cu), tungsten (W), cobalt (Co), ruthenium (Ru), manganese (Mn), titanium (Ti), tantalum (Ta), aluminum (Al), and a combination thereof.

In example embodiments, the metal-containing layer 156L may be formed of a Mo layer. In this case, an atomic layer deposition (ALD) process or a chemical vapor deposition (CVD) process using a Mo precursor may be performed to form the metal-containing layer 156L. When the metal-containing layer 156L is formed of a Mo layer, the Mo precursor may be selected from MoCl₃, MoCl₅, MoOCl₄, MoCl₆, Mo(CO)₆, MoO₂Cl₂, MoOCl₄, MoF₆, an organic Mo compound, and a combination thereof. In example embodiments, the organic Mo compound may be selected from molybdenum acetylacetonate, biscyclopentadienyl molybdenum dihydride, bisethylcyclopentadienyl molybdenum dihydride, bisisopropylcyclopentadienyl molybdenum dihydride, biscyclopentadienylimide molybdenum, and a combination thereof. However, the types of Mo precursors that may be used to form the metal-containing layer 156L may be varied from those described above.

In example embodiments, the metal-containing layer 156L may be formed of a Mo layer. The Mo layer may include a Mo nucleation layer formed on the metal silicide layer 152, and a bulk Mo layer filling the source/drain contact hole (CAH) on the Mo nucleation layer. The Mo nucleation layer may be formed by a PVD process. The bulk Mo layer may be formed by a bottom-up filling method using an ALD process. In forming the bulk Mo layer by the bottom-up filling method, a process temperature, a process pressure, a flow rate of the Mo precursor, a partial pressure of a reducing gas (e.g., H₂ gas) may be adjusted so that there is a nucleation delay on the exposed surfaces of the insulating layers exposed from an inner sidewall of the source/drain contact hole CAH, e.g., the insulating liner 146, the inter-gate insulating layer 148, and the insulating layer 149.

In other example embodiments, the metal-containing layer 156L may include a growth initiation layer formed on the metal silicide layer 152 and including tungsten (W) or a W-containing material, and a bulk Mo layer formed on the growth initiation layer by the bottom-up charging method described above to fill the source/drain contact hole CAH.

In example embodiments, the metal-containing layer 156L may also be formed in a relatively large opening or trench formed in a scribe lane region or a peripheral circuit region of the substrate 110, as well as in the source/drain contact hole CAH. Also, although FIG. 8H illustrates that the source/drain contact hole CAH is completely filled with the metal-containing layer 156L up to the entrance thereof, an empty space may remain on the metal-containing layer 156L in the relatively large opening or trench after the metal-containing layer 156L is formed. In this case, an overburden Mo layer (not shown) covering the metal-containing layer 156L may be further formed on the substrate 110 in order to completely fill the relatively large opening or trench. The overburden Mo layer may be formed by a PVD process, for example.

In example embodiments, the first length L11 of a portion covering the inner sidewall of the source/drain contact hole CAH in the overhang portion OH of the local capping layer 154L in a vertical direction (the Z direction) may be about 30% to 50% of the second length L12 from the entrance of the source/drain contact hole CAH to the lowermost surface of the source/drain contact hole CAH defined on the metal silicide layer 152 in the vertical direction (the Z direction). In example embodiments, the first length L11 may be less than about 50% of the second length L12. For example, in the vertical direction (the Z direction), the first length L11 may be greater than about 30% and less than about 50% of the second length L12.

When the local capping layer 154L includes a metal, adhesion between the overhang portion OH of the local capping layer 154L and the metal-containing layer 156L may be improved. As a length of a portion not covered with the overhang portion OH of the local capping layer 154L in the inner sidewall of the source/drain contact hole CAH in a vertical direction (the Z direction) (i.e., a length obtained by subtracting the first length L11 from the second length L12) increases, a nucleation delay effect at the exposed surfaces of the insulating layers exposed from inner sidewalls of the source/drain contact hole CAH, e.g., the exposed surfaces of the insulating liner 146 and the inter-gate insulating layer 148, may increase, which may be advantageous for forming the metal-containing layer 156L in a bottom-up filling manner.

Referring to FIG. 8I, in a resultant structure of FIG. 8I, portions outside the source/drain contact hole CAH in the local capping layer 154L and the metal-containing layer 156L may be removed using a CMP process to expose an upper surface of the insulating layer 149. As a result, the conductive plug 156 filling the source/drain contact hole CAH may be obtained from the metal-containing layer 156L, and a ring-shaped local capping pattern 154 formed of portions remaining in the source/drain contact hole CAH in the overhang portion OH of the local capping layer 154L may be obtained. The local capping pattern 154 and the conductive plug 156 may constitute the source/drain contact structure CA.

Because the local capping pattern 154 has a ring shape surrounding the outer sidewall of the upper end of the conductive plug 156, the local capping pattern 154 may physically fix the conductive plug 156 so that at least a portion of the conductive plug 156 may not escape from the source/drain contact hole CAH during removal of portions of the local capping layer 154L and the metal-containing layer 156L outside the source/drain contact hole CAH using a CMP process or a follow-up process. In addition, when the local capping layer 154L includes a metal, adhesion between the overhang portion OH of the local capping layer 154L and the metal-containing layer 156L may be improved, so that the physical fixing effect of the conductive plug 156 by the local capping pattern 154 may be further improved.

Thereafter, referring again to FIGS. 2A and 2B, the etch stop layer 182 and the interlayer insulating layer 184 may be sequentially formed on a resultant structure of FIG. 8I to form the upper insulating structure 180, and form the via contacts CAV connected to the source/drain contact structure CA and the gate contact structures CB connected to the gate lines GL, thereby manufacturing the IC device 100 described above with reference to FIGS. 1 and 2A to 2D.

In example embodiments, in order to form the gate contact structures CB, after the gate contact hole CBH exposing the gate line GL through the upper insulating structure 180, the insulating layer 149, and the insulating capping line 140, a process similar to the process of forming the source/drain contact structure CA described above with reference to FIGS. 8G to 8I may be performed on a resultant structure.

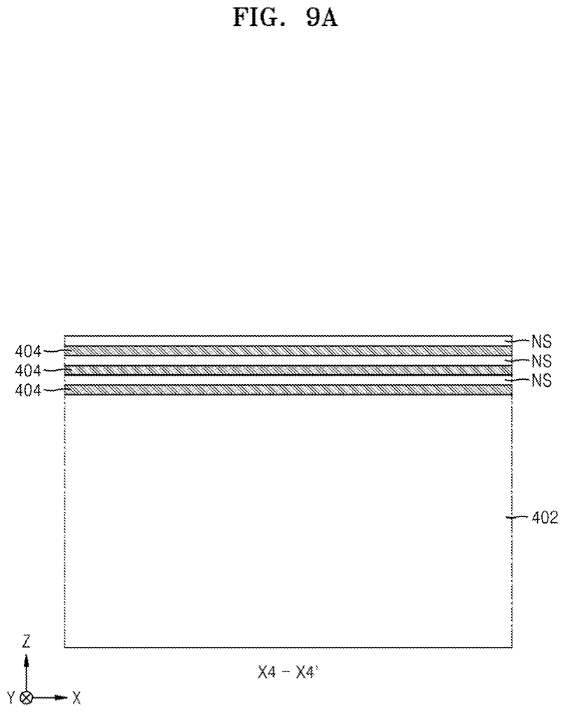

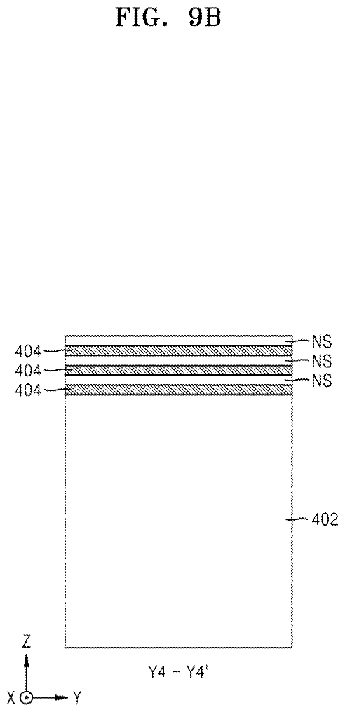

FIGS. 9A to 15 are cross-sectional views illustrating a process sequence of a method of manufacturing an IC device, according to other example embodiments, in which FIGS. 9A, 10A, 11A, 12A, 13A, 14A, and 15 are cross-sectional views according to a process sequence of portions corresponding to the cross-section X4-X4′ of FIG. 6, and FIGS. 9B, 10B, 11B, 12B, 13B, and 14B are cross-sectional views illustrating a process sequence of a portion corresponding to the cross-section Y4-Y4′ of FIG. 6. A method of manufacturing the IC device 400 illustrated in FIGS. 6, 7A, and 7B is described with reference to FIGS. 9A to 15. In FIGS. 9A to 15, the same reference numerals as those in FIGS. 6, 7A, and 7B denote the same members, and detailed descriptions thereof are omitted herein.

Referring to FIGS. 9A and 9B, a plurality of sacrificial semiconductor layers 404 and a plurality of nanosheet semiconductor layers NS may be alternately stacked one by one on a substrate 402. The sacrificial semiconductor layers 404 and the nanosheet semiconductor layers NS may be formed of different semiconductor materials. In example embodiments, the sacrificial semiconductor layers 404 may be formed of SiGe, and the nanosheet semiconductor layers NS may be formed of Si.

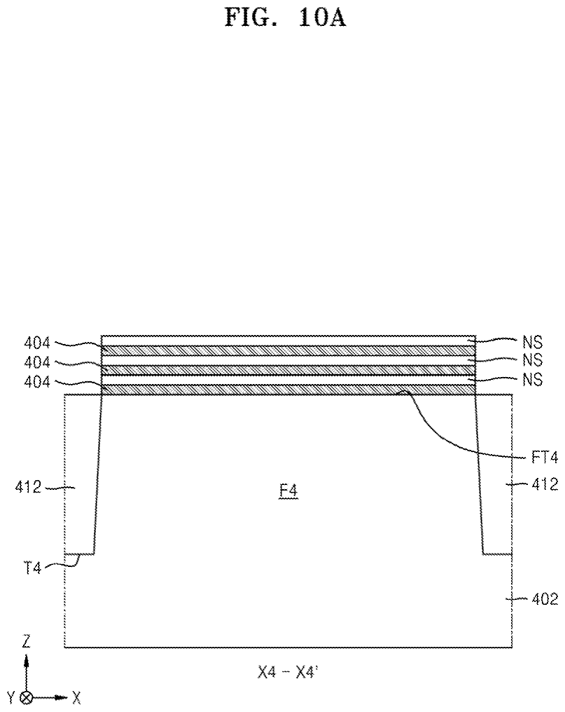

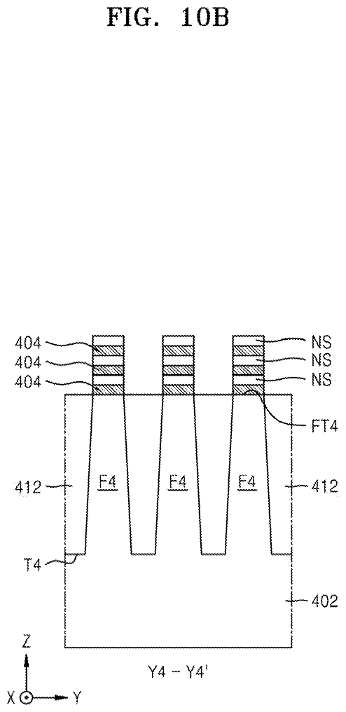

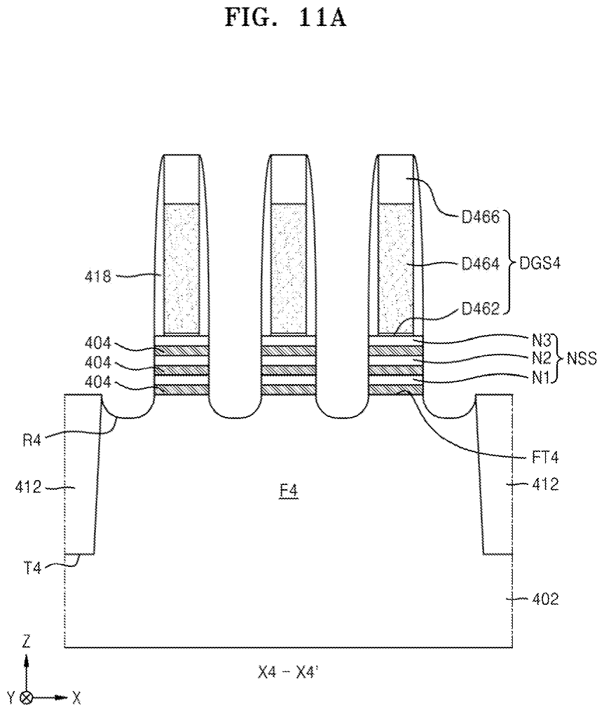

Referring to FIGS. 10A and 10B, portions of the sacrificial semiconductor layers 404, the nanosheet semiconductor layers NS, and the substrate 402 may be etched to form a trench T4. A device separation layer 412 may be formed in the trench T4. As a result, the fin-type active region F4 defined by the trench T4 may be formed. A stacked structure of the sacrificial semiconductor layers 404 and the nanosheet semiconductor layers NS remains on a top surface FT4 of the fin-type active region F4.

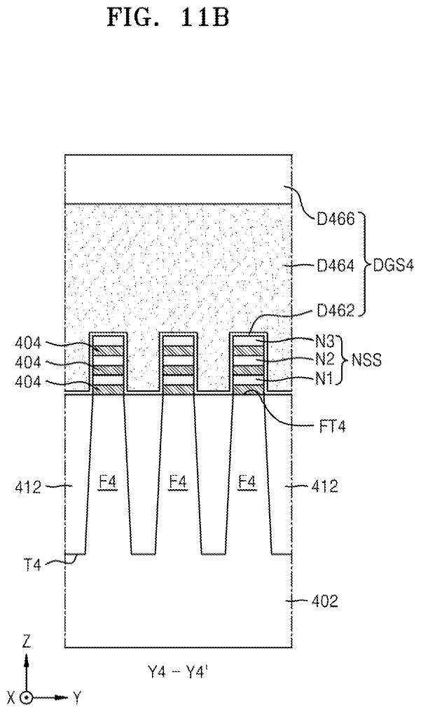

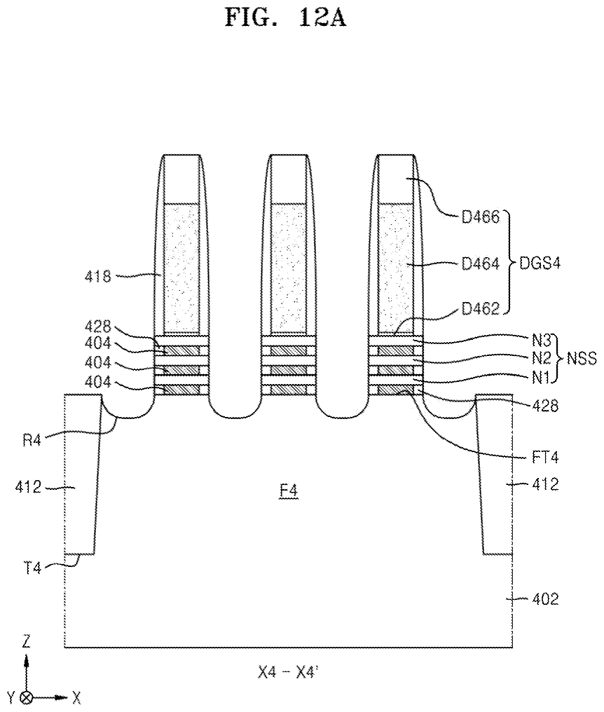

Referring to FIGS. 11A and 11B, a plurality of dummy gate structures DGS4 may be formed on the stacked structure of the sacrificial semiconductor layers 404 and the nanosheet semiconductor layers NS in a resultant structure of FIGS. 10A and 10B. A plurality of outer insulating spacers 418 may be formed to cover both sidewalls of each of the dummy gate structures DGS4. Thereafter, a portion of each of the sacrificial semiconductor layers 404 and the nanosheet semiconductor layers NS may be etched using the dummy gate structures DGS4 and the outer insulating spacers 418 as etch masks to divide the nanosheet semiconductor layers NS into a plurality of nanosheet stacks NSS including a plurality of nanosheets N1, N2, and N3. Thereafter, the fin-type active region F4 exposed between each of the nanosheet stacks NSS may be etched to form a plurality of recess regions R4 on the fin-type active region F4.

Each of the dummy gate structures DGS4 may be elongated in a second horizontal direction (the X direction). Each of the dummy gate structures DGS4 may have a structure in which an insulating layer D462, a dummy gate layer D464, and a capping layer D466 are sequentially stacked. In example embodiments, the insulating layer D462 may be formed of silicon oxide, the dummy gate layer D464 may be formed of polysilicon, and the capping layer D466 may be formed of silicon nitride.

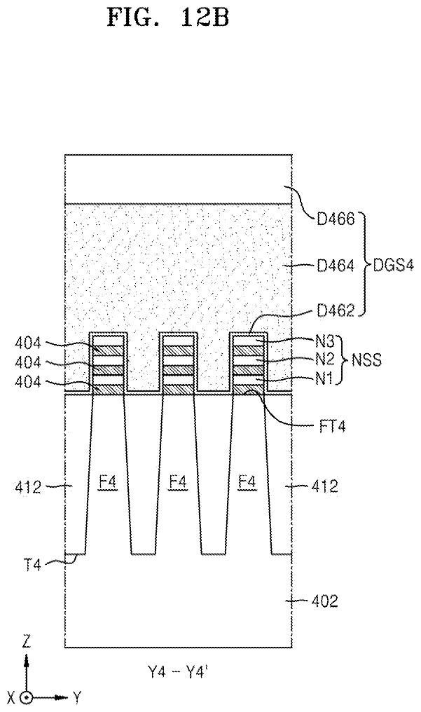

Referring to FIGS. 12A and 12B, in a resultant structure of FIGS. 11A and 11B, a portion of each of the sacrificial semiconductor layers 404 exposed near the recess regions R4 may be removed to form a plurality of indent regions between each of the nanosheets N1, N2, and N3 and between the first nanosheet N1 and the top surface FT4. Thereafter, a plurality of inner insulating spacers 428 may be formed to fill the indent regions.

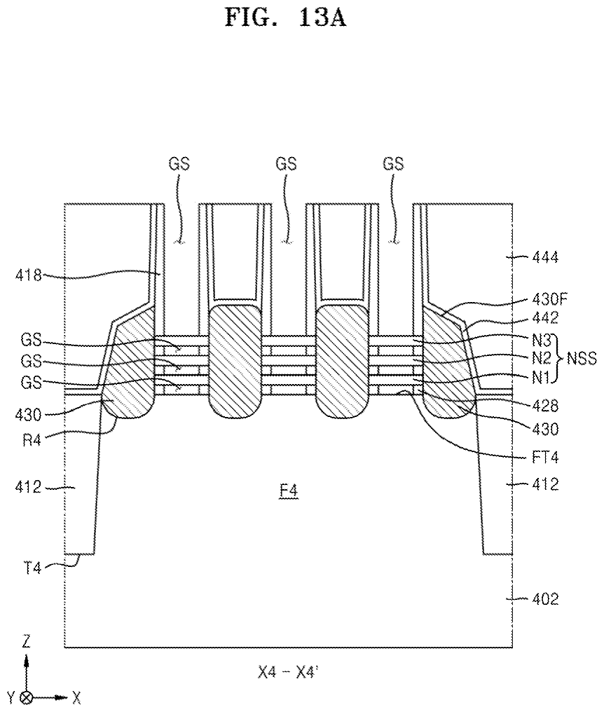

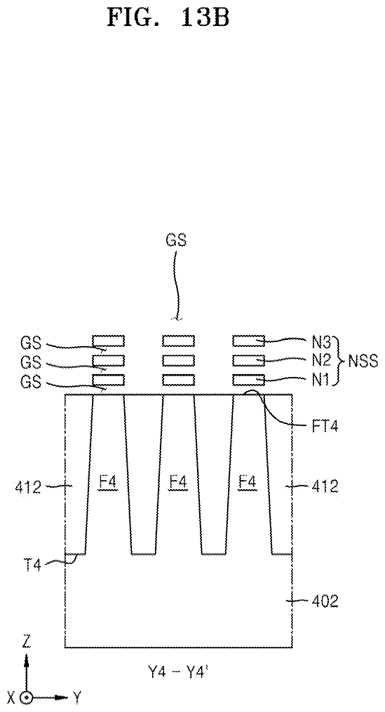

Referring to FIGS. 13A and 13B, in a resultant structure of FIGS. 12A and 12B, a semiconductor material may be epitaxially grown from an exposed surface of each of the recess regions R4 and an exposed surface of each of the nanosheets N1, N2, and N3 to form a plurality of source/drain regions 430. Here, at least one facet 430F may be formed on a surface of the source/drain region 430 adjacent to the device separation layer 412 and facing the device separation layer 412, among the source/drain regions 430. Accordingly, the source/drain region 430 adjacent to the device separation layer 412 may be formed to have a volume less than the source/drain region 430 relatively away from the device separation layer 412. Thereafter, an insulating liner 442 may be formed to cover a resultant structure in which the source/drain regions 430 are formed, an inter-gate insulating layer 444 may be formed on the insulating liner 442, and then a top surface of each of the insulating liner 442 and the inter-gate insulating layer 444 may be planarized to expose a top surface of the capping layer D466 (see FIGS. 12A and 12B).

Thereafter, the dummy gate structures DGS4 illustrated in FIGS. 12A and 12B may be removed to prepare a gate space GS. The sacrificial semiconductor layers 404 may be removed through the gate space GS to expand the gate space GS to a space between each of the nanosheets N1, N2, and N3 and a space between the first nanosheet N1 and the top surface FT4.

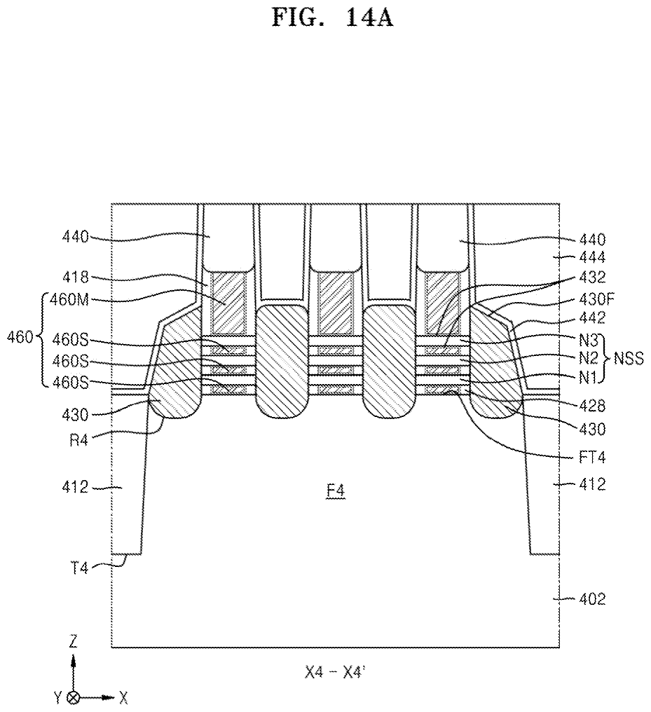

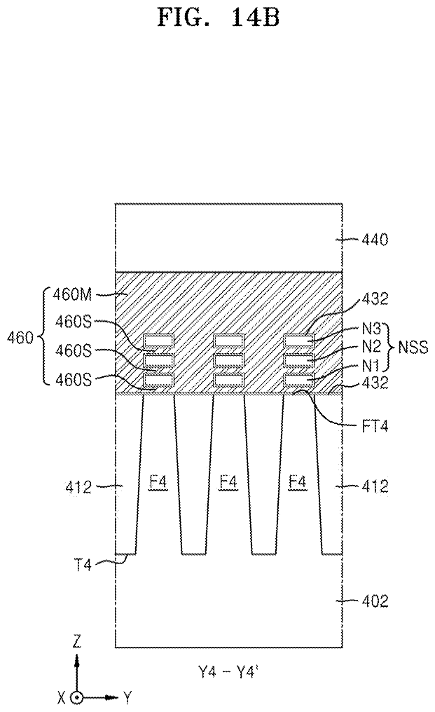

Referring to FIGS. 14A and 14B, a gate insulating layer 432 covering the exposed surfaces of the nanosheets N1, N2, and N3 and the fin-type active region F4 may be formed, a plurality of gate lines 460 filling the gate space GS on the gate insulating layer 432 may be formed, and thereafter, an upper portion of the gate lines 460 and an upper portion of each of the gate insulating layer 432 and the outer insulating spacers 418 adjacent thereto may be removed so that an upper space of each of the gate spaces GS is empty. Thereafter, an upper space of each of the gate spaces GS may be filled with an insulating capping line 440. A planarization process may be performed, while the gate lines 460 and the insulating capping line 440 are formed, so that a height of each of the insulating liner 442 and the inter-gate insulating layer 444 may be lowered.

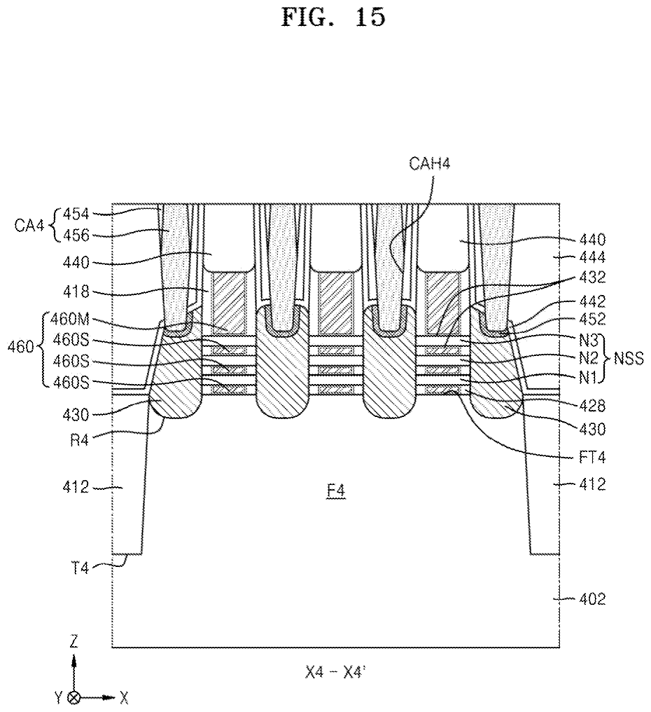

Referring to FIG. 15, the inter-gate insulating layer 444 and the insulating liner 442 may be partially etched to form a plurality of source/drain contact holes CAH4 exposing the source/drain regions 430. Thereafter, a portion of the source/drain region 430 may be removed by an anisotropic etching process through the source/drain contact hole CAH4 so that the source/drain contact hole CAH4 may be elongated toward the substrate 402.

Thereafter, in a similar manner to that of the process of forming the metal silicide layer 152 described above with reference to FIG. 8F, a metal silicide layer 452 may be formed on the source/drain region 430 exposed from a bottom side of the source/drain contact hole CAH4, and in a similar manner to that of the process of forming the source/drain contact structure CA described above with reference to FIGS. 8G to 8I, a local capping pattern 454 and a conductive plug 456 may be sequentially formed in the source/drain contact hole CAH4 to form a source/drain contact structure CA4.

Thereafter, referring to FIGS. 7A and 7B, an etch stop layer 482 and an interlayer insulating layer 484 sequentially covering a resultant structure of FIG. 15 may be formed to form an upper insulating structure 480, and a gate contact structure CB4 connected to the gate line 460 may be formed. In order to form the gate contact structure CB4, processes similar to the process of forming the source/drain contact structure CA described above with reference to FIGS. 8G to 8I may be performed.

Also, referring to FIG. 6, a plurality of source/drain via contacts CAV4 connected to the source/drain contact structures CA4 may be formed. In example embodiments, the source/drain via contacts CAV4 and the gate contact structures CB4 may be simultaneously formed. In other example embodiments, the source/drain via contacts CAV4 and the gate contact structures CB4 may be sequentially formed through separate processes. In this case, the source/drain via contacts CAV4 may be first formed, and then the gate contact structures CB4 may be formed, or the gate contact structures CB4 may be first formed, and then the source/drain via contacts CAV4 may be formed.

The method of manufacturing the IC device 100 illustrated in FIGS. 1 and 2A to 2D and the method of manufacturing the IC device 400 illustrated in FIGS. 6 and 7A and 7B are described as an example with reference to FIGS. 8A to 15, but various IC devices having various structures modified or changed from the IC device 200 illustrated in FIG. 3, the IC device 300A illustrated in FIG. 4, and the IC device 300B illustrated in FIG. 5 may be formed by applying various modifications with reference to the above descriptions.

By way of summation and review, as line widths and pitches of metal wiring layers included in an IC device are reduced, it may become increasingly important to suppress an increase in resistance of metal wiring layers, to improve electrical characteristics and reliability.

As described above, embodiments relate to an integrated circuit (IC) device including a metal wiring layer.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An integrated circuit device, comprising:
a conductive region disposed on a substrate;
an insulating structure including a contact hole disposed in the conductive region, and extending from the conductive region in a vertical direction;
a local capping pattern having an outer sidewall in contact with an upper portion of an inner wall of the contact hole, having an inner sidewall facing an inside of the contact hole, and having a width gradually increasing in a horizontal direction away from the substrate; and
a conductive plug passing through the insulating structure through the contact hole in the vertical direction, having a lower sidewall in contact with the insulating structure and an upper sidewall in contact with the local capping pattern, and including a first metal.

2. The integrated circuit device as claimed in claim 1, wherein a portion of the conductive plug defined by the upper sidewall of the conductive plug has a width gradually decreasing in the horizontal direction away from the substrate.

3. The integrated circuit device as claimed in claim 1, wherein the local capping pattern is disposed concentrically with the conductive plug, and has a ring shape surrounding the upper sidewall of the conductive plug.

4. The integrated circuit device as claimed in claim 1, wherein the conductive region includes a metal silicide layer.

5. The integrated circuit device as claimed in claim 1, wherein the conductive region includes a metal layer.

6. The integrated circuit device as claimed in claim 1, wherein the local capping pattern includes a silicon-containing insulating layer, a metal nitride layer, a metal oxynitride layer, a metal-doped insulating layer, or a combination thereof.

7. The integrated circuit device as claimed in claim 1, wherein the local capping pattern includes a material which is the same as a material of at least a portion of the insulating structure.

8. The integrated circuit device as claimed in claim 1, wherein a first length of the local capping pattern is less than a second length of the contact hole in the vertical direction.

9. The integrated circuit device as claimed in claim 1, wherein the local capping pattern includes a second metal that is different from the first metal.

10. The integrated circuit device as claimed in claim 1, wherein the first metal is selected from molybdenum (Mo), copper (Cu), tungsten (W), cobalt (Co), ruthenium (Ru), manganese (Mn), titanium (Ti), tantalum (Ta), aluminum, (Al), and a combination thereof.

11. The integrated circuit device as claimed in claim 1, wherein:
the conductive region includes an epitaxial semiconductor layer and a metal silicide layer interposed between the epitaxial semiconductor layer and the conductive plug,
the conductive plug includes molybdenum (Mo), and
the local capping pattern includes a silicon-containing insulating layer, a metal nitride layer, a metal oxynitride layer, a metal-doped insulating layer, and a combination thereof.

12. The integrated circuit device as claimed in claim 1, further comprising:
an upper insulating structure including an upper contact hole disposed in the conductive plug extending in the vertical direction;
an upper local capping pattern having an outer sidewall in contact with an upper portion of an inner wall of the upper contact hole away from the conductive plug, having an inner sidewall facing an inside of the upper contact hole, and having a width gradually increasing in the horizontal direction away from the substrate; and
an upper conductive plug passing through the upper insulating structure through the upper contact hole in the vertical direction, having a lower sidewall in contact with the upper insulating structure and an upper sidewall in contact with the upper local capping pattern, and including a second metal.

13. An integrated circuit device, comprising:
a source/drain region disposed on a substrate, and having a recess surface on an upper surface thereof;
a metal silicide layer disposed on the recess surface of the source/drain region, and including a first metal;
an insulating structure including a contact hole disposed in the metal silicide layer and extending from the metal silicide layer in a vertical direction;
a local capping pattern having an outer sidewall in contact with an upper portion of an inner wall of the contact hole away from the substrate, having an inner sidewall facing an inside of the contact hole, and having a width gradually increasing in a horizontal direction away from the substrate; and
a conductive plug passing through the insulating structure through the contact hole in the vertical direction, having a lower sidewall in contact with the insulating structure and an upper sidewall in contact with the local capping pattern, and including a second metal that is different from the first metal.

14. The integrated circuit device as claimed in claim 13, wherein:
the local capping pattern is concentrically disposed with the conductive plug, and has a ring shape surrounding an upper end of the conductive plug, and
a first upper surface of the local capping pattern and a second upper surface of the conductive plug extend from the same plane in the horizontal direction.

15. The integrated circuit device as claimed in claim 13, wherein the local capping pattern includes a silicon-containing insulating layer, a metal nitride layer, a metal oxynitride layer, a metal-doped insulating layer, or a combination thereof.

16. The integrated circuit device as claimed in claim 13, wherein a first length of the local capping pattern is greater than about 30% and less than about 50% of a second length of the contact hole.

17. The integrated circuit device as claimed in claim 13, wherein the local capping pattern includes a third metal that is different from the second metal.

18. The integrated circuit device as claimed in claim 13, wherein the second metal is selected from molybdenum (Mo), copper (Cu), tungsten (W), cobalt (Co), ruthenium (Ru), manganese (Mn), titanium (Ti), tantalum (Ta), aluminum, (Al), and a combination thereof.

19. An integrated circuit device, comprising:
a fin-type active region protruding from a substrate;
a source/drain region disposed in the fin-type active region;
a metal silicide layer in contact with an upper surface of the source/drain region;
a gate line extending from the fin-type active region in a direction intersecting with the fin-type active region;
an insulating structure disposed in the source/drain region, the metal silicide layer, and the gate line;
a source/drain contact structure passing through a first portion of the insulating structure, and connected to the source/drain region through the metal silicide layer; and
a gate contact structure passing through a second portion of the insulating structure in a vertical direction, and configured to be connected to the gate line,
wherein at least one of the source/drain contact structure and the gate contact structure includes:
a local capping pattern having an outer sidewall in contact with an upper portion of an inner wall of a contact hole formed in the insulating structure, having an inner sidewall facing an inside of the contact hole, and having a width gradually increasing in a horizontal direction away from the substrate; and
a conductive plug passing through the insulating structure through the contact hole in the vertical direction, having a lower sidewall in contact with the insulating structure and an upper sidewall in contact the local capping pattern, and including a first metal.

20. The integrated circuit device as claimed in claim 19, wherein:
the local capping pattern is concentrically disposed with the conductive plug to have a ring shape surrounding an upper end of the conductive plug,
a first upper surface of the local capping pattern and a second upper surface of the conductive plug extend from the same plane in the horizontal direction,
the local capping pattern includes a silicon-containing insulating layer, a metal nitride layer, a metal oxynitride layer, a metal-doped insulating layer, or a combination thereof, and
the conductive plug includes molybdenum (Mo).
